(19) United States
(12) Patent Application Publication
(10) Pub. No.: US 2025/0234712 A1
(43) Pub. Date: Jul. 17, 2025

(54) DISPLAY DEVICE AND METHOD OF PROVIDING THE SAME

(71) Applicant: Samsung Display Co., LTD., Yongin-si (KR)

(72) Inventors: Joon Yong PARK, Yongin-si (KR); Hee Min PARK, Yongin-si (KR); Hyun Eok SHIN, Yongin-si (KR); Hee Jun YANG, Yongin-si (KR)

(21) Appl. No.: 18/785,484

(22) Filed: Jul. 26, 2024

(30) Foreign Application Priority Data
Jan. 16, 2024 (KR) 10-2024-0006643

(51) Int. Cl. H10K 59/122; H10K 59/12; H10K 59/80

(52) U.S. Cl. CPC H10K 59/122; H10K 59/1201; H10K 59/873

(57) ABSTRACT

A display device including a display area including an emission area and a non-emission area. The non-emission area includes a pixel defining layer, and first and second bank structures each including a first bank layer including a side surface facing the emission area and a second bank layer including a tip which protrudes further than the side surface of the first bank layer. The emission area includes a light emitting layer in contact with the side surface of the first bank layer, a cathode electrode on the light emitting layer and in contact with the side surface of the first bank layer, and an auxiliary electrode on the cathode electrode and in contact with the side surface of the first bank layer and with the of the second bank layer, and a first encapsulation layer on the second bank structure and on the auxiliary electrode.

This application claims priority to Korean Patent Application No. 10-2024-0006643 filed on Jan. 16, 2024, and all the benefits accruing therefrom under 35 U.S.C. 119, the contents of which in its entirety are herein incorporated by reference.

### BACKGROUND

### 1. Field

The present disclosure relates to a display device and a method of fabricating (or providing) the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light emitting display device. Among the flat panel display devices, in the light emitting display device, since each of pixels of a display panel includes a light emitting element capable of emitting light by itself, an image can be displayed without a backlight unit providing light to the display panel.

As various electronic devices have developed, the demand for high-resolution display devices is increasing. Since high-resolution display devices require high pixel integration density, the spacing between light emitting elements which overlap each emission area may be narrowed. Accordingly, a high-resolution display device may be formed by a pattern process which forms individual pixels rather than a mask process.

### SUMMARY

Aspects of the present disclosure provide a high-resolution display device by forming (or providing) a light emitting element by a photo pattern process without a mask, and also provide a display device in which moisture permeation defects caused by moisture and oxygen are solved.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

However, effects according to the embodiments of the present disclosure are not limited to those exemplified above and various other effects are incorporated herein.

In an embodiment of the disclosure, a display device includes a substrate including an emission area and a non-emission area, a pixel defining layer located on the non-emission area of the substrate, a first bank structure located on the pixel defining layer, and including a first bank layer and a second bank layer having a first tip which protrudes toward the emission area beyond a side surface of the first bank layer facing the emission area, a second bank structure located on the first bank structure, and including a third bank layer and a fourth bank layer having a second tip which protrudes toward the emission area beyond a side surface of the third bank layer facing the emission area, a light emitting layer located on the emission area of the substrate, and in contact with the side surface of the first bank layer, a cathode electrode located on the light emitting layer, and in contact with the side surface of the first bank layer, an auxiliary electrode located on the cathode electrode, and in contact with the side surface of the first bank layer and the first tip of the second bank layer, and a first encapsulation layer on the second bank structure and the auxiliary electrode.

In an embodiment, the display device may further include an organic pattern located on the first tip, containing the same material as the light emitting layer, and spaced apart from the light emitting layer, an electrode pattern located on the organic pattern, containing the same material as the cathode electrode, and spaced apart from the cathode electrode, and an auxiliary electrode pattern located on the electrode pattern, containing the same material as the auxiliary electrode, and spaced apart from the auxiliary electrode.

In an embodiment, the electrode pattern may entirely cover the organic pattern, and the auxiliary electrode pattern entirely covers the electrode pattern.

In an embodiment, the second bank layer may have a side surface facing the emission area, and the side surface of the second bank layer includes a first portion in contact with the organic pattern, a second portion in contact with the electrode pattern, and a third portion in contact with the auxiliary electrode pattern.

In an embodiment, the second portion may be located between the first portion and the third portion.

In an embodiment, the organic pattern, the electrode pattern, and the auxiliary electrode pattern may overlap in a direction perpendicular to the second tip and the substrate.

In an embodiment, the second bank layer may have a first surface facing the first bank layer, the first surface includes a first portion in contact with the first bank layer, a second portion in contact with the auxiliary electrode, and a third portion in contact with the first encapsulation layer, and the second portion is located between the first portion and the third portion.

In an embodiment, the first surface of the second bank layer may be entirely covered by the first bank layer, the auxiliary electrode, and the first encapsulation layer.

In an embodiment, the fourth bank layer may have a side surface facing the emission area and a first surface located in a direction opposite to a direction in which the third bank layer is located, and the side surface of the fourth bank layer is entirely in contact with the first encapsulation layer.

In an embodiment, the display device may further include a second encapsulation layer located on the first encapsulation layer, where the first surface of the fourth bank layer and the first encapsulation layer are spaced apart from each other, in a direction perpendicular to the substrate, with the second encapsulation layer interposed therebetween.

In an embodiment, the first surface of the fourth bank layer may be entirely in contact with the second encapsulation layer.

In an embodiment, a part of the first surface of the fourth bank layer may be covered by the first encapsulation layer.

In an embodiment, the display device may further include a residual pattern overlapping the emission area, and located between the substrate and the pixel defining layer in a direction perpendicular to the substrate, where the residual pattern may overlap the first tip and the second tip in the direction perpendicular to the substrate.

In an embodiment, the residual pattern may overlap the organic pattern, the electrode pattern, and the auxiliary electrode pattern in the direction perpendicular to the substrate.

In an embodiment, the display device may further include a third bank structure located between the first bank structure and the second bank structure, where the third bank structure includes a fifth bank layer and a sixth bank layer having a third tip which protrudes toward the emission area beyond a side surface of the fifth bank layer facing the emission area, and the organic pattern, the electrode pattern, and the auxiliary electrode pattern are located on the third tip.

In an embodiment, the organic pattern, the electrode pattern, and the auxiliary electrode pattern located on the first tip, and the organic pattern, the electrode pattern, and the auxiliary electrode pattern located on the third tip may overlap in a direction perpendicular to the substrate.

In an embodiment, the first encapsulation layer entirely may cover the first tip, the second tip, and the third tip, and the side surface of the third bank layer and the side surface of the fifth bank layer are in contact with the first encapsulation layer.

In an embodiment, the display device may further include a fourth bank structure located between the second bank structure and the third bank structure, where the fourth bank structure includes a seventh bank layer and an eighth bank layer having a fourth tip which protrudes toward the emission area beyond a side surface of the seventh bank layer facing the emission area, and the organic pattern, the electrode pattern, and the auxiliary electrode pattern are located on the fourth tip.

In an embodiment, the display device may further include a height of the first bank layer may be greater than a height of the second bank layer.

In an embodiment of the disclosure, a method of fabricating a display device includes forming a substrate including an emission area and a non-emission area, forming an anode electrode on the emission area and a sacrificial layer on the anode electrode, and then forming a pixel defining layer entirely covering the sacrificial layer and the substrate, and a bank structure including a first bank layer, a second bank layer, a third bank layer, a fourth bank layer, a fifth bank layer, a sixth bank layer, a seventh bank layer, and an eighth bank layer which are sequentially stacked, forming a photoresist on the eighth bank layer to expose a portion overlapping the anode electrode, partially removing the pixel defining layer and the bank structure through a first etching process to form a hole exposing the sacrificial layer overlapping the anode electrode, and then performing a second etching process to remove a portion of the sacrificial layer overlapping the hole while forming a first tip of the second bank layer which protrudes toward the hole beyond a side surface of the first bank layer, a second tip of the fourth bank layer which protrudes toward the hole beyond a side surface of the third bank layer, a third tip of the sixth bank layer which protrudes toward the hole beyond a side surface of the fifth bank layer, and a fourth tip of the eighth bank layer which protrudes toward the hole beyond a side surface of the seventh bank layer, and forming a light emitting layer, a cathode electrode, an auxiliary electrode, and a first encapsulation layer entirely on the anode electrode and the eighth bank layer, forming a hard mask at a portion overlapping the anode electrode and a vicinity of the anode electrode, and then removing the light emitting layer, the cathode electrode, the auxiliary electrode, and the first encapsulation layer located in a portion where the hard mask is not formed through a third etching process to form a light emitting element while forming an organic pattern, an electrode pattern, and an auxiliary electrode pattern on each of the first tip, the second tip, and the third tip, and forming a cavity between the first encapsulation layer and a top surface of the eighth bank layer to expose a top surface of the eighth bank layer, where in the forming of the auxiliary electrode, the auxiliary electrode is in contact with the side surface of the first bank layer and the first tip of the second bank layer.

The display device of an embodiment may provide a high-resolution display device by forming a light emitting element by a photo pattern process without a mask, and also provide a display device in which moisture permeation defects caused by moisture and oxygen are solved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic perspective view of an electronic device according to an embodiment;

FIG. 2 is a perspective view illustrating a display device included in the electronic device according to an embodiment;

FIG. 3 is a schematic cross-sectional view of the display device of FIG. 2;

FIG. 4 is a plan view illustrating the disposition of the emission area in the display area of FIG. 3;

FIG. 5 is a schematic cross-sectional view of the display area taken along line X1-X1′ of FIG. 4;

FIG. 6 is an enlarged schematic cross-sectional view of the first emission area in FIG. 5;

FIG. 7 is an enlarged cross-sectional view of area A of FIG. 6;

FIG. 8 is a schematic cross-sectional view of the display area taken along line X1-X1′ of FIG. 4 according to an embodiment;

FIG. 9 is a schematic cross-sectional view of the display area taken along line X1-X1′ of FIG. 4 according to an embodiment;

FIG. 10 is a schematic cross-sectional view of the display area taken along line X1-X1′ of FIG. 4 according to an embodiment; and

FIGS. 11 to 20 are cross-sectional views illustrating an embodiment of a schematic method of fabricating (or providing) the display element layer and the thin film encapsulation layer included in the display device of FIG. 5.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout. Within the Figures and the text of the disclosure, a reference number indicating a singular form of an element may also be used to reference a plurality of the singular element.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). The term such as “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

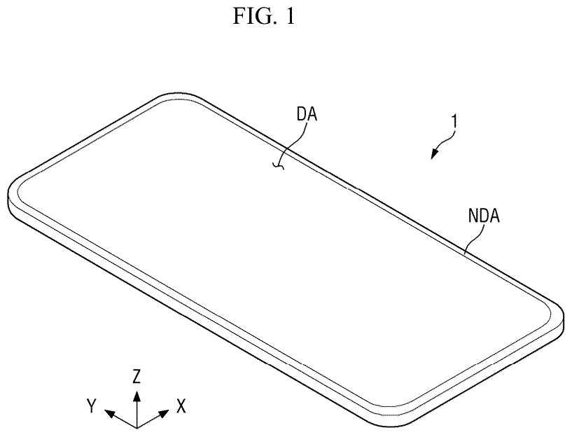

FIG. 1 is a schematic perspective view of an electronic device 1 according to an embodiment.

Referring to FIG. 1, the electronic device 1 displays a moving image or a still image. The electronic device 1 may refer to any electronic device providing (or having) a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

FIG. 1 defines a first direction (X-axis direction), a second direction (Y-axis direction), and a third direction (Z-axis direction) variously crossing or intersecting each other. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and/or the third direction (Z-axis direction) may be perpendicular to each other, without being limited thereto. It may be understood that the first direction (X-axis direction) refers to a horizontal direction in the drawing, the second direction (Y-axis direction) refers to a vertical direction in the drawing, and the third direction (Z-axis direction) refers to an upward and downward direction (e.g., a thickness direction) in the drawing. One direction and another direction among the first to third directions detailed above may cross each other to define a plane.

In the following specification, unless otherwise stated, “direction” may refer to both of directions extending along a same direction (e.g., one direction and an opposite direction to the one direction). Further, when it is necessary to distinguish both “directions” extending in both of opposing directions, one side will be referred to as “one side in the direction” and the other side will be referred to as “the other side in the direction.” Referring to FIG. 1, a direction in which an arrow indicating a direction is directed is referred to as one side, and an opposite direction thereto is referred to as the other side.

Hereinafter, for simplicity of description, when referring to the electronic device 1 or the surfaces of each member constituting the electronic device 1, one major surface facing one side in the direction in which the image is displayed, that is, the third direction (Z-axis direction) is referred to as a top surface, and the major surface as the opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing the relative position of each of the members of the electronic device 1, one side of the third direction (Z-axis direction) may be referred to as an upper side and the other side of the third direction (Z-axis direction) may be referred to as a lower side.

The shape of the electronic device 1 may be variously modified. For example, the electronic device 1 may have a planar shape such as a rectangular shape elongated to define a major direction in a horizontal direction, a rectangular shape elongated to define a major direction in a vertical direction, a square shape, a quadrilateral shape with rounded corners (vertices), other polygonal shapes and a circular shape.

The electronic device 1 may include a display area DA and a non-display area NDA which is adjacent to the display area DA. The display area DA is an area (e.g., a planar area) where a screen can be displayed (e.g., a display screen which displays an image), and the non-display area NDA is an area (e.g., a planar area) where a screen (or image) is not displayed. The display area DA may also be referred to as an active region, and the non-display area NDA may also be referred to as a non-active region. The display area DA may substantially occupy the center of the electronic device 1. Here, the display area DA may be spaced apart from an outer edge of the electronic device 1.

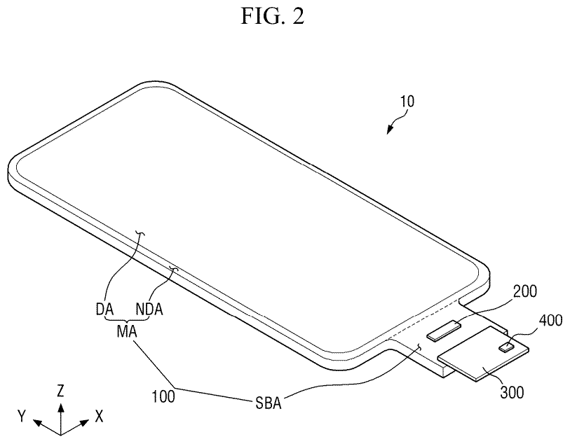

FIG. 2 is a perspective view illustrating a display device 10 included in the electronic device 1 according to an embodiment.

Referring to FIG. 2, the electronic device 1 according to an embodiment may include the display device 10. The display device 10 may provide a screen at which an image is displayed by the electronic device 1. Examples of the display device 10 may include an inorganic light emitting diode display device, an organic light emitting display device, a quantum dot light emitting display device, a plasma display device and a field emission display device. In the following description, a case where an organic light emitting diode display device is applied as a display device will be exemplified, but the present disclosure is not limited thereto, and other display devices may be applied within the same scope of technical spirit.

The display device 10 may have a planar shape similar to the shape of the electronic device 1. For example, the display device 10 may have a shape similar to a rectangular shape, in plan view, having short sides in the first direction (X-axis direction) and long sides in the second direction (Y-axis direction). The edge where the short side in the first direction (X-axis direction) and the long side in the second direction (Y-axis direction) meet may be rounded to have a curvature, but is not limited thereto and may be formed at a right angle. The planar shape of the display device 10 is not limited to a quadrilateral shape, and may be formed or provided in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA. The main region MA may include the display area DA including pixels displaying an image and the non-display area NDA which is adjacent to the display area DA, such as being disposed around or along the display area DA.

The display area DA may emit light from a plurality of openings or a plurality of emission areas EA to be described later. For example, the display panel 100 may include a pixel circuit including switching elements, a pixel defining layer defining an emission area EA or an opening, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto. In the following drawings, a case where the self-light emitting element is an organic light emitting diode is illustrated by way of example.

The non-display area NDA may be an area outside the display area DA such as being closer to the outer edge of the electronic device 1 than the display area DA. The non-display area NDA may be defined as an edge area of the main region MA of the display panel 100.

The sub-region SBA may be a region extending from one side of the main region MA. The sub-region SBA may include a flexible material which is bendable, foldable or rollable so as to be bent, folded or rolled. For example, when the display device 10 is bent at the sub-region SBA, the sub-region SBA may overlap the main region MA in a thickness direction (e.g., the third direction (Z-axis direction)). The sub-region SBA may include the display driver 200 and a pad portion which is connected to the circuit board 300. In an embodiment, the sub-region SBA may be omitted, and the display driver 200 and the pad portion may be located in the non-display area NDA. In an embodiment, the sub-region SBA may be considered a portion of the non-display area NDA, without being limited thereto.

The display driver 200 may output signals and voltages as electrical signals for driving the display panel 100. The display driver 200 may be formed (or provided) as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction by bending of the sub-region SBA. For another example, the display driver 200 may be mounted on the circuit board 300.

The circuit board 300 as a component external to the display panel 100 may be attached to the display panel 100 at the pad portion of the display panel 100 by using an anisotropic conductive film (ACF). The circuit board 300 may be a flexible printed circuit board, a printed circuit board, or a flexible film such as a chip on film.

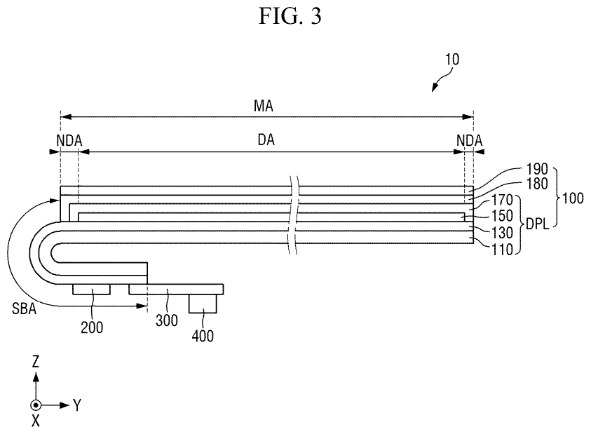

The touch driver 400 may be mounted on the circuit board 300. The touch driver 400 may be connected to a touch sensor layer 180 (see FIG. 3) of the display panel 100. The touch driver 400 may be formed as an integrated circuit.

FIG. 3 is a schematic cross-sectional view of the display device 10 of FIG. 2. FIG. 3 illustrates a side view of the display device 10 of FIG. 2 which is bent at the sub-region SBA.

Referring to FIG. 3, the display panel 100 may include a display layer DPL, the touch sensor layer 180, and a color filter layer 190. The display layer DPL may include a substrate 110, a thin film transistor layer 130 of a pixel circuit within a pixel circuit layer, a display element layer 150, and a thin film encapsulation layer 170 as an encapsulation layer.

The substrate 110 may be a base substrate or a base member. The substrate 110 may be a flexible substrate which can be bent, folded or rolled. For example, the substrate 110 may include a polymer resin such as polyimide (PI), but is not limited thereto. In an embodiment, the substrate 110 may include a glass material or a metal material.

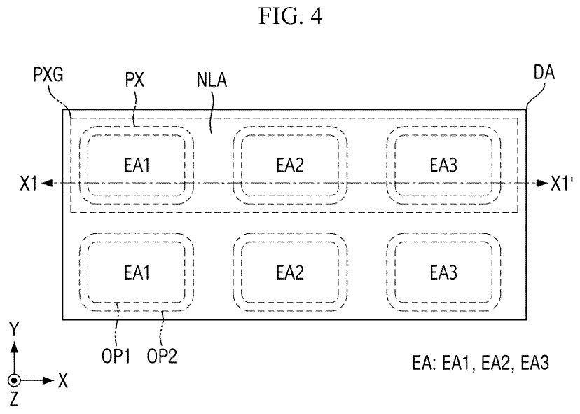

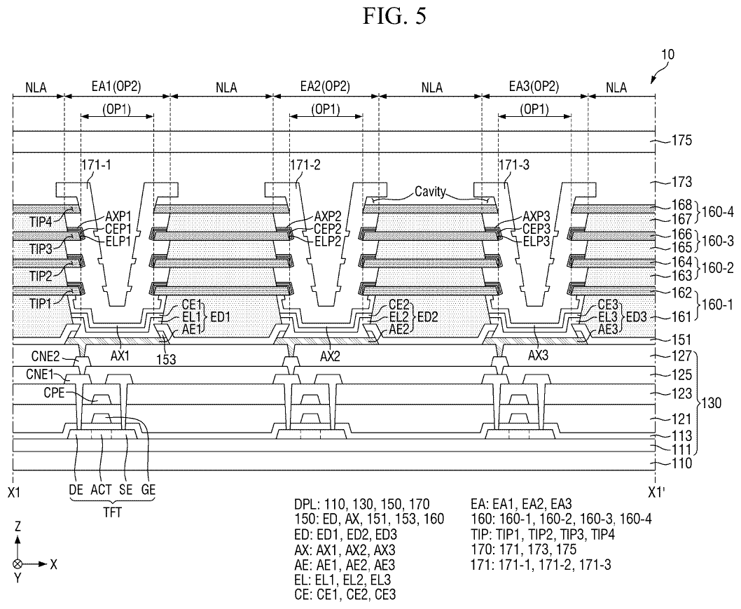

The thin film transistor layer 130 may be disposed on the substrate 110. The thin film transistor layer 130 may be located in the display area DA, the non-display area NDA, and the sub-region SBA. The thin film transistor layer 130 may include a plurality of thin film transistors TFT (see FIG. 5) constituting a pixel PX (see FIG. 4).

The display element layer 150 may be located on the thin film transistor layer 130. The display element layer 150 may be positioned to overlap the display area DA. The display element layer 150 may include a plurality of display elements ED (see FIG. 5). For example, the display element of an embodiment may include at least one of an organic light emitting diode (LED) including an organic light emitting layer, a quantum dot LED including a quantum dot light emitting layer, an inorganic LED including an inorganic semiconductor, and a micro LED, but is not limited thereto.

The thin film encapsulation layer 170 may be positioned on the display element layer 150. The thin film encapsulation layer 170 may be positioned to overlap the display area DA and the non-display area NDA. The thin film encapsulation layer 170 may cover the top surface and the side surface of the display element layer 150 and protect the display element layer 150 from external oxygen and moisture.

The touch sensor layer 180 may be located on the thin film encapsulation layer 170. The touch sensor layer 180 may be positioned to overlap the display area DA and the non-display area NDA. The touch sensor layer 180 may sense an external input such as from the user's touch or from an input tool by using a mutual capacitance method or a self-capacitance method.

The color filter layer 190 may be positioned on the touch sensor layer 180. The color filter layer 190 may be positioned to overlap the display area DA and the non-display area NDA. The color filter layer 190 may absorb a part of light coming from the outside of the display device 10 to reduce reflected light due to external light. Accordingly, the color filter layer 190 may prevent color distortion caused by reflection of the external light.

Since the color filter layer 190 is directly disposed on the touch sensor layer 180, the display device 10 may not require a separate substrate for the color filter layer 190. Accordingly, the thickness of the display device 10 may be relatively small. In addition, the color filter layer 190 may be omitted depending on the embodiment.

As illustrated in FIG. 3, a portion of the display layer DPL overlapping the sub-region SBA may be bendable to be bent. When a portion of the display layer DPL is bent, the display driver 200, the circuit board 300, and the touch driver 400 may overlap the main region MA in the third direction (Z-axis direction).

FIG. 4 is a plan view illustrating the disposition of the emission area EA in the display area DA of FIG. 3.

Referring to FIG. 4, the display area DA of an embodiment may include a plurality of first to third emission areas EA1, EA2, and EA3 and a non-emission area NLA which is adjacent to the emission areas EA. The non-emission area NLA may be positioned to surround the plurality of first to third emission areas EA1, EA2, and EA3.

The non-emission area NLA may block each light emitted from the plurality of first to third emission areas EA1, EA2, and EA3. Accordingly, the non-emission area NLA may assist in preventing the respective lights emitted from the plurality of first to third emission areas EA1, EA2, and EA3 from being mixed with each other. A pixel defining layer 151 (see FIG. 5) and a bank layer 160 (see FIG. 5), which will be described later, may be located in the non-emission area NLA.

The emission area EA may include a first emission area EA1, a second emission area EA2, and a third emission area EA3 emitting light of different colors. The first to third emission areas EA1, EA2, and EA3 may emit red, green, or blue light, respectively, and the color of the light emitted from each of the first to third emission areas EA1, EA2 and EA3 may be different depending on the type of a light emitting element ED, which will be described later. In an embodiment, the first emission area EA1 may emit red light of a first color, the second emission area EA2 may emit green light of a second color, and the third emission area EA3 may emit green light of a third color, but the present disclosure is not limited thereto. In the drawing, the size (e.g., a planar dimension) and shape (e.g., a planar shape) of each of the first to third emission areas EA1, EA2, and EA3 are illustrated to be the same, but are not limited thereto. The size and shape of each of the first to third emission areas EA1, EA2, and EA3 may be freely adjusted according to required characteristics.

The plurality of first to third emission areas EA1, EA2, and EA3 may be defined by a first opening OP1 and a second opening OP2. For example, the first opening OP1 may be defined by the pixel defining layer 151, which will be described later, and the second opening OP2 may be defined by a bank structure 160, which will be described later. In plan view, the second opening OP2 may completely surround the first opening OP1, and the second opening OP2 may be completely surrounded by the non-emission area NLA.

In some embodiments, at least one first emission area EA1, at least one second emission area EA2, and at least one third emission area EA3 disposed adjacent to each other may constitute one pixel group PXG. The pixel group PXG may be a minimum unit which emits white light. However, the type and/or number of the first to third respective emission areas EA1, EA2, and EA3 constituting the pixel group PXG may be changed depending on the embodiments.

FIG. 5 is a schematic cross-sectional view of the display area DA taken along line X1-X1′ of FIG. 4. FIG. 5 is a partial cross-sectional view of the display device 10 overlapping the display area DA and illustrates a schematic cross section of the display layer DPL. That is, FIG. 5 illustrates a cross section of the substrate 110, the thin film transistor layer 130, the display element layer 150, and the thin film encapsulation layer 170 of the display device 10. Since the substrate 110 is explained in FIG. 3 above, it will be omitted.

Referring to FIG. 5, the thin film transistor layer 130 may be located on the substrate 110. The thin film transistor layer 130 may include a first buffer layer 111, the thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be positioned on the substrate 110. The first buffer layer 111 may include an inorganic layer capable of preventing penetration of air or moisture. For example, the first buffer layer 111 may include a plurality of inorganic layers alternately stacked.

The thin film transistor TFT may be disposed on the first buffer layer 111, and may constitute a pixel circuit of each of the plurality of pixels PX. For example, the thin film transistor TFT may be a switching transistor or a driving transistor of the pixel circuit. The thin film transistor TFT may include an active layer ACT, a source electrode SE, a drain electrode DE, and a gate electrode GE.

The active layer ACT may be located on the first buffer layer 111. The active layer ACT may overlap the gate electrode GE in the third direction (Z-axis direction), and may be insulated from the gate electrode GE by the gate insulating layer 113. In a part of the active layer ACT, a material of the active layer ACT may be made into or provided as a conductor (e.g., electrical conductor) to form the source electrode SE and the drain electrode DE.

The gate electrode GE may be located on the gate insulating layer 113. The gate electrode GE may overlap the active layer ACT with the gate insulating layer 113 interposed therebetween.

The gate insulating layer 113 may be located on the active layer ACT. The gate insulating layer 113 may cover the active layer ACT and the first buffer layer 111, and may insulate the active layer ACT from the gate electrode GE. The gate insulating layer 113 may include a contact hole defined therein and through which the first connection electrode CNE1 passes.

The first interlayer insulating layer 121 may cover the gate electrode GE and the gate insulating layer 113. The first interlayer insulating layer 121 may include a contact hole defined therein and through which the first connection electrode CNE1 passes. The contact hole of the first interlayer insulating layer 121 may be connected to or overlapped with the contact hole of the gate insulating layer 113 and the contact hole of the second interlayer insulating layer 123.

The capacitor electrode CPE may be located on the first interlayer insulating layer 121. The capacitor electrode CPE may overlap the gate electrode GE in the third direction (Z-axis direction). The capacitor electrode CPE and the gate electrode GE may together form a capacitance.

The second interlayer insulating layer 123 may cover the capacitor electrode CPE and the first interlayer insulating layer 121. The second interlayer insulating layer 123 may include a contact hole through which the first connection electrode CNE1 passes. The contact hole of the second interlayer insulating layer 123 may be connected to the contact hole of the first interlayer insulating layer 121 and the contact hole of the gate insulating layer 113.

The first connection electrode CNE1 may be located on the second interlayer insulating layer 123. The first connection electrode CNE1 may electrically connect the drain electrode DE of the thin film transistor TFT to the second connection electrode CNE2. The first connection electrode CNE1 may extend through a contact hole provided in the first interlayer insulating layer 121, the second interlayer insulating layer 123, and the gate insulating layer 113 to be in contact (e.g., physical and/or electrical) with the drain electrode DE of the thin film transistor TFT.

The first via layer 125 may cover the first connection electrode CNE1 and the second interlayer insulating layer 123. The first via layer 125 may flatten the lower structure, such as to planarize a profile of the underlying layers. The first via layer 125 may include a contact hole defined therein and through which the second connection electrode CNE2 passes.

The second connection electrode CNE2 may be located on the first via layer 125. The second connection electrode CNE2 may extend through a contact hole formed in the first via layer 125 to be in contact with the first connection electrode CNE1. The second connection electrode CNE2 may electrically connect the first connection electrode CNE1 to first to third anode electrodes AE1, AE2, and AE3.

The second via layer 127 may cover the second connection electrode CNE2 and the first via layer 125. The second via layer 127 may include a contact hole defined therein and through which the first to third anode electrodes AE1, AE2, and AE3 pass.

The display element layer 150 may be located on the second via layer 127. The display element layer 150 may include the light emitting elements ED, an auxiliary electrodes AX, the pixel defining layer 151, a residual pattern 153, and the bank structure 160.

The light emitting element ED of an embodiment may include an anode electrode AE, a light emitting layer EL, and a cathode electrode CE. The light emitting elements ED may include a first light emitting element ED1 disposed in the first emission area EA1, a second light emitting element ED2 disposed in the second emission area EA2, and a third light emitting element ED3 disposed in the third emission area EA3.

The light emitting elements ED overlapping the first to third emission areas EA1, EA2, and EA3 may emit lights of different colors depending on the material of the light emitting layer EL. For example, the first light emitting element ED1 may emit the red light of the first color, the second light emitting element ED2 may emit the green light of the second color, and the third light emitting element ED3 may emit the blue light of the third color.

The anode electrode AE may be located on the second via layer 127. The anode electrode AE may be electrically connected to the drain electrode DE of the thin film transistor TFT through the first connection electrode CNE1 and the second connection electrode CNE2.

The anode electrodes AE may include a first anode electrode AE1 disposed in the first emission area EA1, a second anode electrode AE2 disposed in the second emission area EA2, and a third anode electrode AE3 disposed in the third emission area EA3. The first anode electrode AE1, the second anode electrode AE2, and the third anode electrode AE3 may be located to be spaced apart from each other on the second via layer 127 and in a direction along the thin film transistor layer 130.

In an embodiment, the anode electrode AE may have a stacked structure formed by stacking a material layer having a high work function, such as indium tin oxide (ITO), indium zinc oxide (IZO), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or a combination thereof. For example, the anode electrode AE may have a multilayer structure of ITO/Mg, ITO/MgF, ITO/Ag, and ITO/Ag/ITO, but are not limited thereto.

The pixel defining layer 151 may be located on the second via layer 127 and the anode electrode AE. Solid portions of the pixel defining layer 151 may separate and insulate the first to third anode electrodes AE1, AE2, and AE3 from each other. The pixel defining layer 151 in an embodiment may include a solid portion which defines the first opening OP1. The pixel defining layer 151 may include a sidewall which defines the first opening OP1. The pixel defining layer 151 as including the solid portion and the openings defined therein may be disposed on the entire surface of the second via layer 127, and may expose a part of the top surface of the anode electrode AE to outside the pixel defining layer 151. In other words, the pixel defining layer 151 may expose the anode electrode AE at a portion overlapping the first opening OP1, and the light emitting layer EL may be directly located on the anode electrode AE at a portion overlapping the first opening OP1.

The pixel defining layer 151 may include an inorganic insulating material. For example, the pixel defining layer 151 may include silicon oxide, silicon nitride, and silicon oxynitride.

The bank structure 160 of an embodiment may be located on the pixel defining layer 151 at a portion overlapping the non-emission area NLA. The bank structure 160 of an embodiment may define the second opening OP2. That is, solid portions as banks of the bank structure 160 may define the respective openings therein. The second opening OP2 with or without the first opening OP1 may define a bank opening.

The bank structure 160 of an embodiment may include a first bank structure 160-1, a second bank structure 160-2, a third bank structure 160-3, and a fourth bank structure 160-4. The first to fourth bank structures 160-1, 160-2, 160-3, and 160-4 be sequentially stacked in the third direction (Z-axis direction).

The first bank structure 160-1 of an embodiment may be located on the pixel defining layer 151. The first bank structure 160-1 of an embodiment may include a first bank layer 161 and a second bank layer 162 including different metal materials from each other. The first bank structure 160-1 of an embodiment may include (or define) a first tip TIP1 protruding toward the emission area EA. The first bank layer 161 of an embodiment may electrically connect the first to third cathode electrodes CE1, CE2, and CE3 positioned to respectively overlap the first to third emission areas EA1, EA2, and EA3.

The second bank structure 160-2 of an embodiment may be located on the first bank structure 160-1. The second bank structure 160-2 may include a first bank layer 163 and a second bank layer 164 including different metal materials from each other. The second bank structure 160-2 of an embodiment may include a second tip TIP2 protruding toward the emission area EA.

The third bank structure 160-3 of an embodiment may be located on the second bank structure 160-2. The third bank structure 160-3 may include a first bank layer 165 and a second bank layer 166 including different metal materials from each other. The third bank structure 160-3 of an embodiment may include a third tip TIP3 protruding toward the emission area EA.

The fourth bank structure 160-4 of an embodiment may be located on the third bank structure 160-3. The fourth bank structure 160-4 may include a first bank layer 167 and a second bank layer 168 including different metal materials from each other. The fourth bank structure 160-4 of an embodiment may include a fourth tip TIP4 protruding toward the emission area EA.

A respective first bank layer may include a sidewall defining the second opening OP2. A corresponding second bank layer may protrude further than the sidewall to define a respective tip among the tips TIP. The tips TIP included in the bank structure 160 of an embodiment may be positioned to overlap each other and/or the emission area EA, and the first to fourth tips TIP1, TIP2, TIP3, and TIP4 may overlap each other in the third direction (Z-axis direction). One or more of the various first and second bank layers may define a bank of the bank structure 160 which is disposed in the non-emission area NLA.

In the display device 10 of an embodiment, the bank structure 160 includes the tips TIP, so that the first to third light emitting layers EL1, EL2, and EL3 and the first to third cathode electrodes CE1, CE2, and CE3 which are positioned to respectively overlap the first to third emission areas EA1, EA2, and EA3 may be formed without a separate fine metal mask during a fabrication process of the display device 10. Accordingly, in the display device 10 of an embodiment, it is possible to form the plurality of light emitting elements ED applicable to a high-resolution display device which requires high pixel integration density.

The light emitting layers EL of an embodiment may be located on the anode electrodes AE, respectively. The light emitting layer EL may be an organic light emitting layer made of an organic material, and may be formed on the anode electrode AE by the deposition process. In the light emitting layer EL, when the thin film transistor TFT applies a predetermined voltage to the anode electrode AE and the cathode electrode CE receives a common voltage or a cathode voltage, holes and electrons may move to the light emitting layer EL through a hole transport layer and an electron transport layer, respectively, and may be combined with each other to emit light in the light emitting layer EL.

The light emitting layers EL may include the first light emitting layer EL1, the second light emitting layer EL2, and the third light emitting layer EL3 respectively disposed in the first to third emission areas EA1, EA2, and EA3. For example, the first light emitting layer EL1 may be the light emitting layer emitting red light of the first color, the second light emitting layer EL2 may be the light emitting layer emitting green light of the second color, and the third light emitting layer EL3 may be the light emitting layer emitting blue light of the third color, but the present disclosure is not limited thereto.

In some embodiments, end portions of the anode electrode AE and the pixel defining layer 151 may be located to be spaced apart from each other in the third direction (Z-axis direction). The residual pattern 153 may be located at a portion or gap where the anode electrode AE and the pixel defining layer 151 are spaced apart from each other. The residual pattern 153 will be described later.

The cathode electrodes CE of an embodiment may be located on the light emitting layers EL, respectively. The cathode electrodes CE may include a transparent conductive material, so that the light generated in the light emitting layer ELs may be emitted. The cathode electrodes CE may receive the common voltage or a low potential voltage. When the anode electrode AE receives a voltage corresponding to a data voltage and the cathode electrode CE receives the low potential voltage, a potential difference is formed between the anode electrode AE and the cathode electrode CE, so that the light emitting layer EL may emit light.

In an embodiment, the cathode electrode CE may include a material layer having a low work function, such as Li, Ca, LiF/Ca, LiF/Al, Al, Mg, Ag, Pt, Pd, Ni, Au Nd, Ir, Cr, BaF, Ba or a compound or combination thereof (e.g., a combination of Ag, Pd, and Cu). The cathode electrode CE may further include a transparent metal oxide layer disposed on the material layer having a low work function.

The cathode electrode CE may include the first cathode electrode CE1, the second cathode electrode CE2, and the third cathode electrode CE3 respectively disposed in the first to third emission areas EA1, EA2, and EA3. The first cathode electrode CE1 may be disposed on the first light emitting layer EL1 in the first emission area EA1, the second cathode electrode CE2 may be disposed on the second light emitting layer EL2 in the second emission area EA2, and the third cathode electrode CE3 may be located on the third light emitting layer EL3 in the third emission area EA3. The first to third cathode electrodes CE1, CE2, and CE3 of an embodiment may not be directly connected, and may be electrically connected through the first bank layer 161.

The auxiliary electrodes AX of an embodiment may be located on the cathode electrodes CE, respectively. The auxiliary electrodes AX of an embodiment may assist in facilitating electrical connection between the cathode electrode CE and the first bank layer 161, and may assist in preventing moisture and oxygen from permeating into the cathode electrode CE.

The auxiliary electrode AX may be made of (or include) transparent conductive oxide (TCO), for example, indium-tin-oxide (ITO), indium-zinc-oxide (IZO), and zinc-indium-tin-oxide (ZITO).

The auxiliary electrode AX may include a first auxiliary electrode AX1, a second auxiliary electrode AX2, and a third auxiliary electrode AX3 respectively disposed in the first to third emission areas EA1, EA2, and EA3. The first auxiliary electrode AX1 may be disposed on the first cathode electrode CE1 in the first emission area EA1, the second auxiliary electrode AX2 may be disposed on the second cathode electrode CE2 in the second emission area EA2, and the third auxiliary electrode AX3 may be disposed on the third cathode electrode CE3 in the third emission area EA3. The first to third auxiliary electrodes AX1, AX2, and AX3 of an embodiment may be electrically connected through the cathode electrode CE and the first bank layer 161.

On the first tip TIP1 of the first bank structure 160-1, a plurality of first to third organic patterns ELP1, ELP2, and ELP3, a plurality of first to third electrode patterns CEP1, CEP2, and CEP3, and a plurality of first to third auxiliary electrode patterns AXP1, AXP2, and AXP3 may be located. The plurality of first to third organic patterns ELP1, ELP2, and ELP3, the plurality of first to third electrode patterns CEP1, CEP2, and CEP3, and the plurality of first to third auxiliary electrode patterns AXP1, AXP2, and AXP3 may be located to surround the first opening OP1 of the pixel defining layer PDL, in a plan view. The plurality of first to third organic patterns ELP1, ELP2, and ELP3, the plurality of first to third electrode patterns CEP1, CEP2, and CEP3, and the plurality of first to third auxiliary electrode patterns AXP1, AXP2, and AXP3 may also be located on the second tip TIP2 of the second bank structure 160-2 and the third tip TIP3 of the third bank structure 160-3.

The first to third organic patterns ELP1, ELP2, and ELP3 may include the same material as the first to third light emitting layers EL1, EL2, and EL3, respectively. Specifically, the first organic pattern ELP1 may include the same material as the first light emitting layer EL1, the second organic pattern ELP2 may include the same material as the second light emitting layer EL2, and the third organic pattern ELP3 may include the same material as the third light emitting layer EL3. The first to third organic patterns ELP1, ELP2, and ELP3 may be traces or patterns formed by disconnection of a respective emission material layer for forming the first to third light emitting layers EL1, EL2, and EL3 due to the tip TIP of the bank structure 160 during the fabrication process of the display device 10.

The first to third electrode patterns CEP1, CEP2, and CEP3 may be located on the first to third organic patterns ELP1, ELP2, and ELP3, respectively. For example, the first electrode pattern CEP1, the second electrode pattern CEP2, and the third electrode pattern CEP3 may be directly located on the first organic pattern ELP1, the second organic pattern ELP2, and the third organic pattern ELP3, respectively. The arrangement relationship between the first to third electrode patterns CEP1, CEP2, and CEP3 and the first to third organic patterns ELP1, ELP2, and ELP3 may be the same as the arrangement pattern between the first to third light emitting layers EL1, EL2, and EL3 and the first to third cathode electrodes CE1, CE2, and CE3. The first to third electrode patterns CEP1, CEP2, and CEP3 may include the same material as the first to third cathode electrodes CE1, CE2, and CE3, respectively. The first to third electrode patterns CEP1, CEP2, and CEP3 may be traces or patterns formed by disconnection of a respective cathode electrode material layer for forming the first to third cathode electrodes CE1, CE2, and CEP3 due to the tip TIP of the bank structure 160 during the fabrication process of the display device 10.

The first to third auxiliary electrode patterns AXP1, AXP2, and AXP3 may be located on the first to third electrode patterns CEP1, CEP2, and CEP3, respectively. For example, the first auxiliary electrode pattern AXP1, the second auxiliary electrode pattern AXP2, and the third auxiliary electrode pattern AXP3 may be directly located on the first electrode pattern CEP1, the second electrode pattern CEP2, and the third electrode pattern CEP3, respectively. The arrangement relationship between the first to third auxiliary electrode patterns AXP1, AXP2, and AXP3 and the first to third electrode patterns CEP1, CEP2, and CEP3 may be the same as the arrangement relationship between the first to third cathode electrodes CE1, CE2, and CE3 and the first to third auxiliary electrodes AX1, AX2, and AX3. The first to third auxiliary electrode patterns AXP1, AXP2, and AXP3 may include the same material as the first to third auxiliary electrodes AX1, AX2, and AX3, respectively. The first to third auxiliary electrodes AX1, AX2, and AX3 may be traces or patterns formed by disconnection of a respective auxiliary electrode material layer for forming the first to third auxiliary electrodes AX1, AX2, and AX3 due to the tip TIP of the bank structure 160 during the fabrication process of the display device 10.

That is, the first to third organic patterns ELP1, ELP2, and ELP3 and the first to third light emitting layers EL1, EL2, and EL3 may be respective patterns of a same first to third emission material layer. Similarly, the first to third electrode patterns CEP1, CEP2, and CEP3 and the first to third cathode electrodes CE1, CE2, and CEP3 may be respective patterns of a same first to third cathode electrode material layer. The first to third electrode patterns CEP1, CEP2, and CEP3 and the first to third cathode electrodes CE1, CE2, and CEP3 may be respective patterns of a same first to third auxiliary electrode material layer. As being in a same layer, elements may be formed in a same process and/or include a same material as each other, elements may be respective portions of a same material layer, elements may be on a same layer by forming an interface with a same underlying or overlying layer, etc., without being limited thereto.

The thin film encapsulation layer 170 as an encapsulation layer may be disposed on the display element layer 150. The thin film encapsulation layer 170 may include at least one inorganic layer to prevent oxygen or moisture from permeating into the display element layer 150. The thin film encapsulation layer 170 may include at least one organic layer to protect the display element layer 150 from foreign substances such as dust. The thin film encapsulation layer 170 of an embodiment may include a first encapsulation layer 171, a second encapsulation layer 173, and a third encapsulation layer 175 which are sequentially stacked.

The first encapsulation layer 171 of an embodiment may be located on the light emitting element ED and the bank structure 160. The first encapsulation layer 171 may be formed by a chemical vapor deposition (CVD) process, and may be formed with a uniform thickness along the profile of the lower structure. Here, the thickness may be defined in a direction normal to a surface on which the first encapsulation layer 171 is provided.

End or edge portions of the first encapsulation layer 171 of an embodiment may be spaced apart from the bank structure 160 in the third direction (Z-axis direction). A cavity (or gap) may be formed at a portion where the first encapsulation layer 171 and the bank structure 160 are spaced apart from each other. In other words, the first encapsulation layer 171 may be spaced apart from the bank structure 160 in the third direction (Z-axis direction) with the cavity interposed therebetween.

The first encapsulation layer 171 may include an inorganic material. For example, the first encapsulation layer 171 may include aluminum oxide, titanium oxide, tantalum oxide, hafnium oxide, zinc oxide, silicon oxide, silicon nitride, and silicon oxynitride.

The first encapsulation layer 171 of an embodiment may include a first inorganic layer 171-1, a second inorganic layer 171-2, and a third inorganic layer 171-3 as patterns which are positioned to overlap the first to third emission area EA1, EA2, and EA3, respectively. The first inorganic layer 171-1, the second inorganic layer 171-2, and the third inorganic layer 171-3 may be spaced apart from each other in the first direction (X-axis direction) with a solid portion of the bank structure 160 interposed therebetween. In other words, the first inorganic layer 171-1, the second inorganic layer 171-2, and the third inorganic layer 171-3 may be located to be spaced apart from each other on the bank structure 160 at a portion overlapping the non-emission area NLA.

In the drawing, the first to third inorganic layers 171-1, 171-2, and 171-3 are illustrated as being formed on the same layer, but the first to third inorganic layers 171-1, 171-2, and 171-3 may be formed in different processes, respectively. Exemplarily, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The fabrication process will be described later.

The second encapsulation layer 173 of an embodiment may be located on the first encapsulation layer 171. The second encapsulation layer 173 may flatten or planarize the stepped portion formed by the first encapsulation layer 171.

The second encapsulation layer 173 may include a polymer-based material. A polymer-based material may include acrylic resin, epoxy resin, silicone resin, silicone acrylic resin, polyimide, polyethylene, or the like.

The third encapsulation layer 175 may be located on the second encapsulation layer 173. The third encapsulation layer 175 may include the same material as the first encapsulation layer 171. The third encapsulation layer 175 can prevent oxygen or moisture from permeating into the first encapsulation layer 171 and the second encapsulation layer 173.

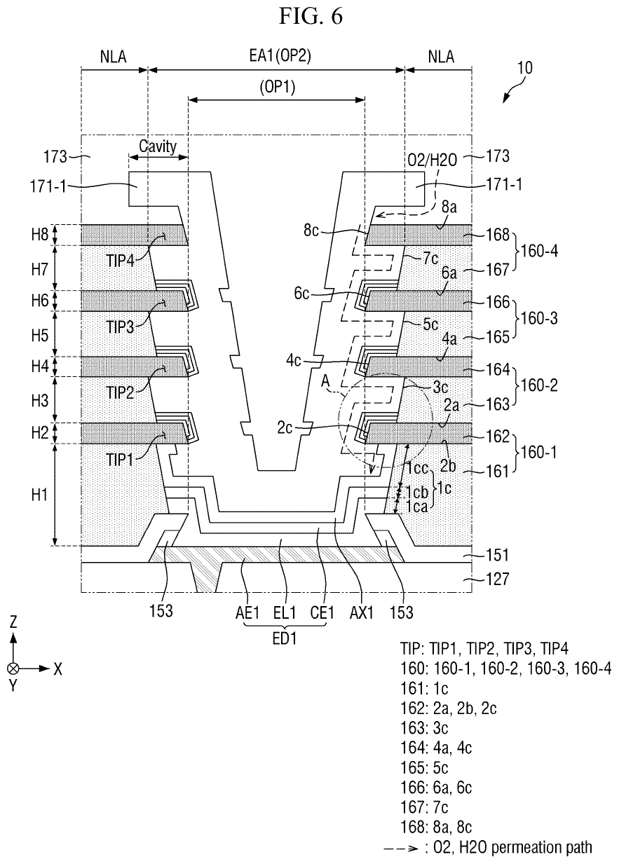

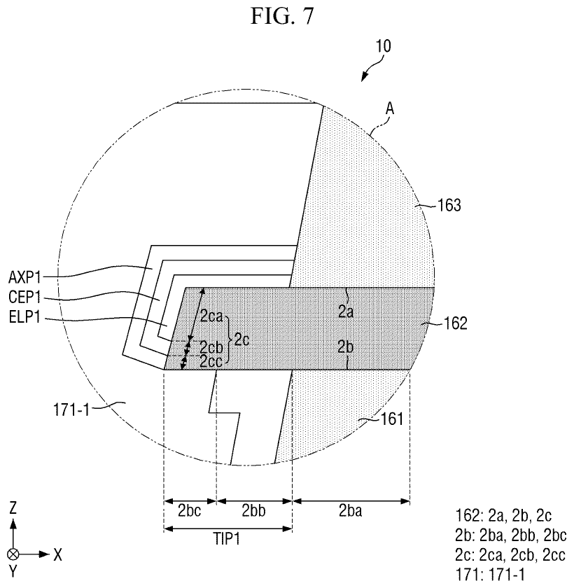

FIG. 6 is an enlarged schematic cross-sectional view of the first emission area EA1 in FIG. 5. FIG. 7 is an enlarged cross-sectional view of area A of FIG. 6.

Referring to FIG. 6, the pixel defining layer 151 may be located on the second via layer 127 and the first anode electrode AE1. Ends of the pixel defining layer 151 may be spaced apart from ends of the first anode electrode AE1 in the third direction (Z-axis direction) to overlap the second opening OP2, and the residual pattern 153 may be located between the pixel defining layer 151 and the first anode electrode AE1. The residual patterns 153 may be disposed to be in contact with both sides of the first light emitting layer EL1 in the first direction (X-axis direction). In addition, the residual pattern 153 may overlap the tip TIP of the bank structure 160 in the third direction (Z-axis direction).

The first bank layer 161 included in the first bank structure 160-1 may be positioned to be in contact with the pixel defining layer 151. The first bank layer 161 may include metal with high electrical conductivity. For example, the first bank layer 161 may include at least one of aluminum (Al) and copper (Cu).

In some embodiments, the first bank layer 161 may include a side surface 1c facing the first opening OP1. The side surface 1c of the first bank layer 161 may be an inclined surface. In other words, the side surface 1c of the first bank layer 161 may be inclined between the first direction (X-axis direction) and the third direction (Z-axis direction). The side surface 1c of the first bank layer 161 may include a structure which is more recessed in the first direction (X-axis direction) than the pixel defining layer 151. That is, the side surface 1c may be outside the first opening OP1.

The first light emitting layer EL1 and the first cathode electrode CE1 of an embodiment may be formed by a thermal deposition process during the fabrication process. The thermal deposition process for forming the first light emitting layer EL1 and the first cathode electrode CE1 may be performed while respective materials are applied tilted in an oblique direction with respect to a surface of the first anode electrode AE1. Therefore, the first light emitting layer EL1 and the first cathode electrode CE1 may be in contact with the side surface 1c of the first bank layer 161 at a portion overlapping the second opening OP2. As described above, the first cathode electrode CE1 of an embodiment may be electrically connected to the first bank layer 161.

In addition, the first auxiliary electrode AX1 of an embodiment may be formed by a sputtering process during the fabrication process. In general, the sputtering process may have higher step coverage characteristics compared to the thermal deposition process. Accordingly, the first auxiliary electrode AX1 may entirely cover the first cathode electrode CE1 at a portion overlapping the first opening OP1, and may entirely cover the first light emitting layer EL1 and the first cathode electrode CE1 located on the side surface 1c of the first bank layer 161 at a portion overlapping the second opening OP2. The first auxiliary electrode AX1 of an embodiment entirely covers the first cathode electrode CE1 and is in contact with the side surface 1c of the first bank layer 161, and thus may assist in connecting (e.g., physically and/or electrically) the first cathode electrode CE1 and the first bank layer 161 to each other without detachment defects. The fabrication process will be described later.

In some embodiments, the side surface 1c of the first bank layer 161 may include a first portion 1ca, a second portion 1cb, and a third portion 1cc depending on structures to be in contact therewith. The side surface 1c and various portions thereof may extend along the Y-axis direction to define a plane of the side surface 1c and various portions thereof.

The first portion Ica may be a portion in contact with the first light emitting layer EL1, the second portion 1cb may be a portion in contact with the first cathode electrode CE1, and the third portion 1cc may be a portion in contact with the first auxiliary electrode AX1. In other words, the side surface 1c of the first bank layer 161 may be entirely covered by end surfaces (or outer surfaces) of the first light emitting layer EL1, the first cathode electrode CE1, and the first auxiliary electrode AX1 which are in the bank opening, and may be entirely in contact with the first light emitting layer EL1, the first cathode electrode CE1, and the first auxiliary electrode AX1. As being in contact, elements may form a (physical) interface therebetween.

The second bank layer 162 of an embodiment may be located on the first bank layer 161. The second bank layer 162 may include a metal material which has high electrical stability and high adhesion to the metal included in the first bank layer 161. In addition, the second bank layer 162 may include a metal material which is more stable in an etching solution used in an etching process than the first bank layer 161. For example, the second bank layer 162 may include any one of molybdenum (Mo), chromium (Cr), gold (Au), titanium (Ti), nickel (Ni), and neodymium (Nd), or an alloy thereof.

In some embodiments, the second bank layer 162 may include a top surface 2a, a bottom surface 2b, and a side surface 2c. The top surface 2a of the second bank layer 162 may be one surface facing the second bank structure 160-2, the bottom surface 2b of the second bank layer 162 may be one surface opposite to the top surface 2a and facing the first bank layer 161, and the side surface 2c of the second bank layer 162 may be one surface facing the first opening OP1 and connecting the top surface 2a and the bottom surface 2b to each other.

The side surface 2c of an embodiment may protrude further than the side surface 1c of the first bank layer 161. Accordingly, an end portion of the second bank layer 162 of an embodiment may have or define the first tip TIP1 which protrudes toward the first emission area EA1 beyond the side surface 1c of the first bank layer 161. An undercut may be formed by the first tip TIP1 and the side surface 1c of the first bank layer 161.

The first tip TIP1 of an embodiment may be formed by the difference between the etching rate of a material for forming the first bank layer 161 and the etching rate of a material for forming the second bank layer 162 for the same etching solution during the fabrication process of the first bank structure 160-1. The fabrication process will be described later.

In some embodiments, a height H1 of the first bank layer 161 may be greater than a height H2 of the second bank layer 162. For example, the height H1 of the first bank layer 161 may be within a range from about 5000 angstroms (Å) to about 8000 Å, and the height H2 of the second bank layer 162 may be within a range from about 1000 Å to about 3000 Å.

Referring to FIG. 7, the first auxiliary electrode AX1 of an embodiment may be in contact with the second bank layer 162 at the bottom surface 2b of the second bank layer 162. As described above, the process for forming the first auxiliary electrode AX1 of an embodiment may be performed as a sputtering process, so that the process for forming the first auxiliary electrode AX1 may have high step coverage characteristics. Therefore, the first auxiliary electrode AX1 of an embodiment may be in contact with a part of the second bank layer 162 as well as the first bank layer 161.

In some embodiments, the bottom surface 2b of the second bank layer 162 may include a first portion 2ba, a second portion 2bb, and a third portion 2bc depending on structures to be in contact therewith. The first portion 2ba of the bottom surface 2b may be a portion in contact with the first bank layer 161, the second portion 2bb of the bottom surface 2b may be a portion in contact with the first auxiliary electrode AX1, and the third portion 2bc of the bottom surface 2b may be a portion in contact with the first inorganic layer 171-1. The second portion 2bb may be located between the first portion 2ba and the third portion 2bc in the first direction (X-axis direction). The bottom surface 2b of the second bank layer 162 may be entirely covered by the first bank layer 161, the first auxiliary electrode AX1, and the first encapsulation layer 171, and the bottom surface 2b of the second bank layer 162 may be entirely in contact with the first bank layer 161, the first auxiliary electrode AX1, and the first encapsulation layer 171.

The first organic pattern ELP1, the first electrode pattern CEP1, and the first auxiliary electrode pattern AXP1 may be located on the top surface 2a of the second bank layer 162 at a portion overlapping the first tip TIP1 of an embodiment. The first auxiliary electrode pattern AXP1 of an embodiment may be positioned to entirely cover the first electrode pattern CEP1, and the first electrode pattern CEP1 may be positioned to entirely cover the first organic pattern ELP1. The first organic pattern ELP1 may be in contact with the top surface 2a and extend from the top surface 2a to be disposed on the side surface 2c of the second bank layer 162.

In some embodiments, the side surface 2c of the second bank layer 162 may include a first portion 2ca, a second portion 2cb, and a third portion 2cc depending on structures to be in contact therewith. The first portion 2ca may be a portion in contact with the first organic pattern ELP1, the second portion 2cb may be a portion in contact with the first electrode pattern CEP1, and the third portion 2cc may be a portion in contact with the first auxiliary electrode pattern AXP1. The second portion 2cb may be located between the first portion 2ca and the third portion 2cc.

The side surface 2c of the second bank layer 162 may be entirely in contact with the first organic pattern ELP1, the first electrode pattern CEP1, and the first auxiliary electrode pattern AXP1, and may be entirely covered by the first organic pattern ELP1, the first electrode pattern CEP1, and the first auxiliary electrode pattern AXP1.

Referring to FIG. 6, the first bank layer 163 included in the second bank structure 160-2 of an embodiment may be located on the first bank structure 160-1. The first bank layer 163 may include metal with high electrical conductivity. For example, the first bank layer 163 may include at least one of aluminum (Al) and copper (Cu).

In some embodiments, the first bank layer 163 may include a side surface 3c facing the first opening OP1. The side surface 3c of the first bank layer 163 may be an inclined surface. In other words, the side surface 3c of the first bank layer 163 may be inclined between the first direction (X-axis direction) and the third direction (Z-axis direction). The side surface 3c of the first bank layer 163 may have a structure which is recessed toward one side in the first direction (X-axis direction) than a side surface 4c of the second bank layer 164.

The side surface 3c of the first bank layer 163 may be entirely covered by the first encapsulation layer 171, and a part of the side surface 3c of the first bank layer 163 may be in contact with the first encapsulation layer 171. Although it is illustrated in the drawing that the first organic pattern ELP1, the first electrode pattern CEP1, and the first auxiliary electrode pattern AXP1 are in contact with the side surface 3c of the first bank layer 163, the present disclosure is not limited thereto. The first organic pattern ELP1, the first electrode pattern CEP1, and the first auxiliary electrode pattern AXP1 may be formed to be spaced apart from the side surface 3c of the first bank layer 163 depending on process conditions.

The second bank layer 164 included in the second bank structure 160-2 of an embodiment may be located on the first bank layer 163. The second bank layer 164 may include a metal material which has high electrical stability and high adhesion to the metal included in the first bank layer 163. In addition, the second bank layer 164 may include a metal material which is more stable in an etching solution used in an etching process than the first bank layer 163. For example, the second bank layer 164 may include any one of molybdenum (Mo), chromium (Cr), gold (Au), titanium (Ti), nickel (Ni), and neodymium (Nd), or an alloy thereof.

In some embodiments, the second bank layer 164 may include a top surface 4a and the side surface 4c. The top surface 4a of the second bank layer 164 may be one surface facing the third bank structure 160-3, and the side surface 4c of the second bank layer 164 may be one surface facing the first opening OP1. The side surface 4c of the second bank layer 164 may protrude toward the first emission area EA1 beyond the side surface 3c of the first bank layer 163. Therefore, the second bank layer 164 may have the second tip TIP2 which protrudes toward the first emission area EA1 beyond the side surface 3c of the first bank layer 163. An undercut may be formed between the second tip TIP2 and the side surface 3c of the first bank layer 163.

The second tip TIP2 of an embodiment may be formed by the difference between the etching rate of a material for forming the first bank layer 163 and the etching rate of a material for forming the second bank layer 164 for the same etching solution during the fabrication process of the second bank structure 160-2. The fabrication process will be described later.

In some embodiments, a height H3 of the first bank layer 163 may be within a range from about 2000 Å to about 3000 Å, and a height H4 of the second bank layer 164 may be within a range from about 1000 Å to about 3000 Å.

The first organic pattern ELP1, the first electrode pattern CEP1, and the first auxiliary electrode pattern AXP1 may be located on the top surface 4a of the second bank layer 164 at a portion overlapping the second tip TIP2 of an embodiment. The first organic pattern ELP1 may be in contact with the top surface 4a and the side surface 4c of the second bank layer 164. The first electrode pattern CEP1 located on the second tip TIP2 may entirely cover the first organic pattern ELP1, and the first auxiliary electrode pattern AXP1 may entirely cover the first electrode pattern CEP1. Redundant descriptions are omitted.

The first bank layer 165 included in the third bank structure 160-3 of an embodiment may be located on the second bank structure 160-2. The first bank layer 165 may include metal with high electrical conductivity. For example, the first bank layer 165 may include at least one of aluminum (Al) and copper (Cu).

In some embodiments, the first bank layer 165 may include a side surface 5c facing the first opening OP1. The side surface 5c of the first bank layer 165 may be an inclined surface. In other words, the side surface 5c of the first bank layer 165 may be inclined between the first direction (X-axis direction) and the third direction (Z-axis direction). The side surface 5c of the first bank layer 165 may have a structure which is recessed toward one side in the first direction (X-axis direction) than a side surface 6c of the second bank layer 166.

The side surface 5c of the first bank layer 165 may be completely covered by the first encapsulation layer 171, and a part of the side surface 5c of the first bank layer 165 may be in contact with the first encapsulation layer 171. Although it is illustrated in the drawing that the first organic pattern ELP1, the first electrode pattern CEP1, and the first auxiliary electrode pattern AXP1 are in contact with the side surface 5c of the first bank layer 165, the present disclosure is not limited thereto. The first organic pattern ELP1, the first electrode pattern CEP1, and the first auxiliary electrode pattern AXP1 may be spaced apart from the side surface 5c of the first bank layer 165 depending on process conditions.

The second bank layer 166 included in the third bank structure 160-3 of an embodiment may be located on the first bank layer 165. The second bank layer 166 may include a metal material which has high electrical stability and high adhesion to the metal included in the first bank layer 165. In addition, the second bank layer 166 may include a metal material which is more stable in an etching solution used in an etching process than the first bank layer 165. For example, the second bank layer 166 may include any one of molybdenum (Mo), chromium (Cr), gold (Au), titanium (Ti), nickel (Ni), and neodymium (Nd), or an alloy thereof.

In some embodiments, the second bank layer 166 may include a top surface 6a and a side surface 6c. The top surface 6a of the second bank layer 166 may be one surface facing the fourth bank structure 160-4, and the side surface 6c of the second bank layer 166 may be one surface facing the first opening OP1. The side surface 6c of the second bank layer 166 may protrude toward the first emission area EA1 beyond the side surface 5c of the first bank layer 165. Therefore, the second bank layer 166 may have the third tip TIP3 which protrudes toward the first emission area EA1 beyond the side surface 5c of the first bank layer 165. An undercut may be formed between the third tip TIP3 and the side surface 5c of the first bank layer 165.

The third tip TIP3 of an embodiment may be formed by the difference between the etching rate of a material for forming the first bank layer 165 and the etching rate of a material for forming the second bank layer 166 for the same etching solution during the fabrication process of the third bank structure 160-3. The fabrication process will be described later.

In some embodiments, a height H5 of the first bank layer 165 may be within a range from about 2000 Å to about 3000 Å, and a height H6 of the second bank layer 166 may be within a range from about 1000 Å to about 3000 Å.

The first organic pattern ELP1, the first electrode pattern CEP1, and the first auxiliary electrode pattern AXP1 may be located on the third tip TIP3 of an embodiment. The first organic pattern ELP1 may be in contact with the top surface 6a and the side surface 6c of the second bank layer 166 at a portion overlapping the third tip TIP3. The first electrode pattern CEP1 located on the third tip TIP3 may entirely cover the first organic pattern ELP1, and the first auxiliary electrode pattern AXP1 may entirely cover the first electrode pattern CEP1. Redundant descriptions are omitted.

The first bank layer 167 included in the fourth bank structure 160-4 of an embodiment may be located on the third bank structure 160-3. The first bank layer 167 may include metal with high electrical conductivity. For example, the first bank layer 167 may include at least one of aluminum (Al) and copper (Cu).

In some embodiments, the first bank layer 167 may include a side surface 7c facing the first opening OP1. The side surface 7c of the first bank layer 167 may be an inclined surface. In other words, the side surface 7c of the first bank layer 167 may be inclined between the first direction (X-axis direction) and the third direction (Z-axis direction). The side surface 7c of the first bank layer 167 may have a structure which is recessed toward one side in the first direction (X-axis direction) than a side surface 8c of the second bank layer 168.

The side surface 7c of the first bank layer 167 may be completely covered by the first encapsulation layer 171, and a part of the side surface 7c of the first bank layer 167 may be in contact with the first encapsulation layer 171. Although it is illustrated in the drawing that the first organic pattern ELP1, the first electrode pattern CEP1, and the first auxiliary electrode pattern AXP1 are in contact with the side surface 7c of the first bank layer 167, the present disclosure is not limited thereto. The first organic pattern ELP1, the first electrode pattern CEP1, and the first auxiliary electrode pattern AXP1 may be spaced apart from the side surface 7c of the first bank layer 167 depending on process conditions.

The second bank layer 168 included in the fourth bank structure 160-4 of an embodiment may be located on the first bank layer 167. The second bank layer 168 may include a metal material which has high electrical stability and high adhesion to metal. The second bank layer 168 may include a metal material which is more stable in an etching solution used in an etching process than the first bank layer 167. For example, the second bank layer 168 may include any one of molybdenum (Mo), chromium (Cr), gold (Au), titanium (Ti), nickel (Ni), and neodymium (Nd), or an alloy thereof.

In some embodiments, the second bank layer 168 may include a top surface 8a and a side surface 8c. The top surface 8a of the second bank layer 168 may be one surface located in the opposite direction facing the first bank layer 167, and the side surface 8c of the second bank layer 168 may be one surface facing the first opening OP1. The side surface 8c of the second bank layer 168 may protrude toward the first emission area EA1 beyond the side surface 7c of the first bank layer 167. Therefore, the second bank layer 168 may have the fourth tip TIP4 which protrudes toward the first emission area EA1 beyond the side surface 7c of the first bank layer 167. An undercut may be formed between the fourth tip TIP4 and the side surface 7c of the first bank layer 167.

The fourth tip TIP4 of an embodiment may be formed by the difference between the etching rate of a material for forming the first bank layer 167 and the etching rate of a material for forming the second bank layer 168 for the same etching solution during the fabrication process of the fourth bank structure 160-4. The fabrication process will be described later.

In some embodiments, a height H7 of the first bank layer 167 may be within a range from about 2000 Å to about 3000 Å, and a height H8 of the second bank layer 168 may be within a range from about 1000 Å to about 3000 Å.

In some embodiments, the top surface 8a of the second bank layer 168 may be spaced apart from the first inorganic layer 171-1 in the third direction (Z-axis direction), such as by a gap. A cavity (Cavity) may be formed between the first inorganic layer 171-1 and the top surface 8a of the second bank layer 168.

During the fabrication process of the display device 10, the material forming the first light emitting layer EL1, the material forming the first cathode electrode CE1, and the material forming the first auxiliary electrode AX1 may be temporarily located between the fourth bank structure 160-4 and the first inorganic layer 171-1, and then removed by a subsequent etching process. That is, the cavity formed between the first inorganic layer 171-1 and the top surface 8a of the second bank layer 168 may be formed by removing the material temporarily forming the first light emitting layer EL1, the material forming the first cathode electrode CE1, and the material forming the first auxiliary electrode AX1, which have been located, by a subsequent etching process during the fabrication process of the display device 10. The fabrication process will be described later.

The first inorganic layer 171-1 of an embodiment may be located on the first auxiliary electrode AX1 at a portion overlapping the first opening OP1, and may completely cover the first light emitting element ED1. In addition, the first inorganic layer 171-1 may cover the first auxiliary electrode AX1, the tip TIP of the bank structure 160, the first organic pattern ELP1, the first electrode pattern CEP1, and the first auxiliary electrode pattern AXP1 at a portion overlapping the second opening OP2. Further, the first inorganic layer 171-1 may cover a part of the bank structure 160 at a portion overlapping the non-emission area NLA.

The first inorganic layer 171-1 of an embodiment may entirely cover the side surface 8c of the second bank layer 168, and may be entirely in contact with the side surface 8c of the second bank layer 168. However, the first inorganic layer 171-1 may not be in contact with the top surface 8a of the second bank layer 168.

The second encapsulation layer 173 of an embodiment may flatten (or planarize) the stepped portion formed by the first inorganic layer 171-1 at a portion overlapping the first emission area EA1 and the non-emission area NLA. Further, the second encapsulation layer 173 may fill the cavity formed between the first inorganic layer 171-1 and the fourth bank structure 160-4. The second encapsulation layer 173 may entirely cover the top surface 8a of the second bank layer 168 included in the fourth bank structure 160-4, and may be entirely in contact with the top surface 8a of the second bank layer 168.

In the display device 10 of an embodiment, the bank structure 160 includes the first to fourth bank structures 160-1, 160-2, 160-3, and 160-4 sequentially stacked in the third direction (Z-axis direction) to form a multilayer bank, so that the permeation path of moisture and oxygen (permeation path of H₂O and O₂) may be formed as long as possible along the thickness direction. Therefore, the display device 10 of an embodiment may solve reliability defects caused by permeation of moisture and oxygen.

Further, the display device 10 of an embodiment includes the first auxiliary electrode AX1 for assisting the electrical connection between the first cathode electrode CE1 and the first bank layer 161, so that the contact defects between the first bank layer 161 and the first cathode electrode CE1 of the display device 10 may be solved.

For simplicity of description, the schematic cross section of the first emission area EA1 and the display element layer 150 and the thin film encapsulation layer 170 which are located to overlap the vicinity of the first emission area EA1 has been illustrated and described, but the display element layer 150 and the thin film encapsulation layer 170 located to overlap the second emission area EA2 and the third emission area EA3 may also have the same structure and characteristics, except for the material of the emission layers respectively corresponding to the color of light emitting at a particular emission area.

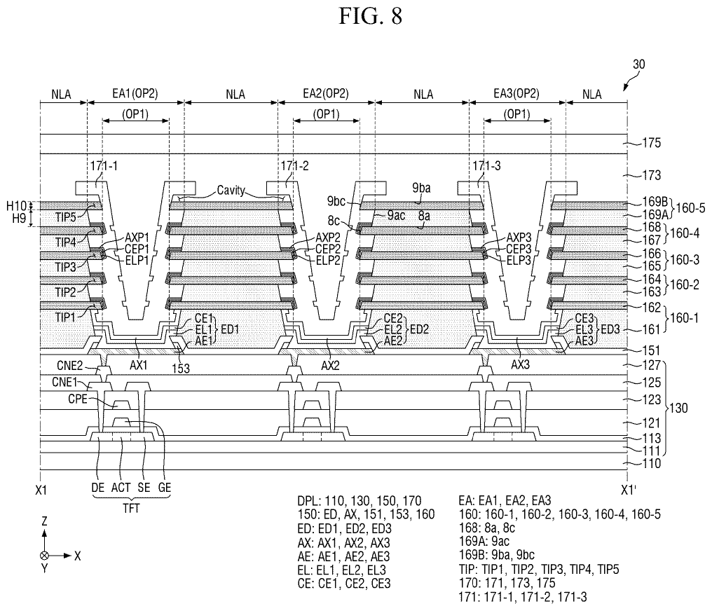

FIG. 8 is is a schematic cross-sectional view of the display area DA taken along line X1-X1′ of FIG. 4 according to an embodiment.

Referring to FIG. 8, a display device 30 of an embodiment is different from the above-described display device 10 in that the bank structure 160 includes the first bank structure 160-1, the second bank structure 160-2, the third bank structure 160-3, the fourth bank structure 160-4, and a fifth bank structure 160-5 sequentially stacked in the third direction (Z-axis direction). That is, the display area DA in FIG. 8 includes five pairs of bank layers making up the first bank structure 160-1, the second bank structure 160-2, the third bank structure 160-3, the fourth bank structure 160-4, and a fifth bank structure 160-5, where the fifth bank structure 160-5 provides the uppermost bank structure. Hereinafter, the common description of the display device 10 and the display device 30 will be omitted, and the differences will be described later.

In some embodiments, the first to third organic patterns ELP1, ELP2, and ELP3, the first to third electrode patterns CEP1, CEP2, and CEP3, and the first to third auxiliary electrode patterns AXP1, AXP2, and AXP3 may be located on the fourth tip TIP4 included in the fourth bank structure 160-4. Specifically, the first organic pattern ELP1, the first electrode pattern CEP1, and the first auxiliary electrode pattern AXP1 may be located on the fourth tip TIP4 at a portion overlapping the first emission area EA1, the second organic pattern ELP2, the second electrode pattern CEP2, and the second auxiliary electrode pattern AXP2 may be located on the fourth tip TIP4 at a portion overlapping the second emission area EA2, and the third organic pattern ELP3, the third electrode pattern CEP3, and the third auxiliary electrode pattern AXP3 may be located on the fourth tip TIP4 at a portion overlapping the third emission area EA3.

The first to third organic patterns ELP1, ELP2, and ELP3, the first to third electrode patterns CEP1, CEP2, and CEP3, and the first to third auxiliary electrode patterns AXP1, AXP2, and AXP3 may cover the side surface 8c of the second bank layer 168, and the first to third organic patterns ELP1, ELP2, and ELP3, the first to third electrode patterns CEP1, CEP2, and CEP3, and the first to third auxiliary electrode patterns AXP1, AXP2, and AXP3 may be in contact with the side surface 8c of the second bank layer 168.

The first to third organic patterns ELP1, ELP2, and ELP3, the first to third electrode patterns CEP1, CEP2, and CEP3, and the first to third auxiliary electrode patterns AXP1, AXP2, and AXP3 may cover a part of the top surface 8a of the second bank layer 168, and the first to third organic patterns ELP1, ELP2, and ELP3 may be in contact with the top surface 8a of the second bank layer 168.

The fifth bank structure 160-5 of an embodiment may include a first bank layer 169A and a second bank layer 169B made of different materials and having different roles. The first bank layer 169A of an embodiment may be located on the fourth bank structure 160-4. The first bank layer 169A may include metal with high electrical conductivity, for example, at least one of aluminum (Al) and copper (Cu).

In some embodiments, the first bank layer 169A may include a side surface 9ac facing the first opening OP1. The side surface 9ac of the first bank layer 169A may be an inclined surface. In other words, the side surface 9ac of the first bank layer 169A may be inclined between the first direction (X-axis direction) and the third direction (Z-axis direction). The side surface 9ac of the first bank layer 169A may have a structure which is recessed toward one side in the first direction (X-axis direction) than a side surface 9bc of the second bank layer 169B.

The first encapsulation layer 171 may entirely cover the side surface 9ac of the first bank layer 169A, and may be in contact with a part of the side surface 9ac of the first bank layer 169A. Although it is illustrated in the drawing that the first to third organic patterns ELP1, ELP2, and ELP3, the first to third electrode patterns CEP1, CEP2, and CEP3, and the first to third auxiliary electrode patterns AXP1, AXP2, and AXP3 are in contact with the side surface 9ac of the first bank layer 169A, the present disclosure is not limited thereto. The first to third organic patterns ELP1, ELP2, and ELP3, the first to third electrode patterns CEP1, CEP2, and CEP3, and the first to third auxiliary electrode patterns AXP1, AXP2, and AXP3 may be spaced apart from the side surface 9ac of the first bank layer 169A depending on process conditions.

The second bank layer 169B included in the fifth bank structure 160-5 of an embodiment may be located on the first bank layer 169A. The second bank layer 169B may include a metal material which has high electrical stability and high adhesion to the metal included in the first bank layer 169A. The second bank layer 169B may include a metal material which is more stable in an etching solution used in an etching process than the first bank layer 169A. For example, the second bank layer 169B may include any one of molybdenum (Mo), chromium (Cr), gold (Au), titanium (Ti), nickel (Ni), and neodymium (Nd), or an alloy thereof.

In some embodiments, the second bank layer 169B may include a top surface 9ba and a side surface 9bc. The top surface 9ba of the second bank layer 169B may be one surface located in the opposite direction facing the first bank layer 169A, and the side surface 9bc of the second bank layer 169B may be one surface facing the first opening OP1.

The side surface 9bc of the second bank layer 169B may protrude from the side surface 9ac of the first bank layer 169A beyond the emission area EA. Accordingly, the second bank layer 169B may have a fifth tip TIP5 which protrudes toward the emission area EA beyond the side surface 9ac of the first bank layer 169A. An undercut may be formed between the fifth tip TIP5 and the side surface 9ac of the first bank layer 169A.

The fifth tip TIP5 of an embodiment may be formed by the difference between the etching rate of a material for forming the first bank layer 169A and the etching rate of a material for forming the second bank layer 169B for the same etching solution during the fabrication process of the fifth bank structure 160-5. In other words, the etching rate of the first bank layer 169A may be higher than the etching rate of the second bank layer 169B in the same etching solution.

In some embodiments, a height H9 of the first bank layer 169A may be within a range from about 2000 Å to about 3000 Å, and a height H10 of the second bank layer 169B may be within a range from about 1000 Å to about 3000 Å.

In some embodiments, the top surface 9ba of the second bank layer 169B may be spaced apart from the first encapsulation layer 171 in the third direction (Z-axis direction). A cavity may be formed between the first encapsulation layer 171 and the top surface 9ba of the second bank layer 169B. Redundant descriptions of the cavity are omitted.

The first encapsulation layer 171 of an embodiment may entirely cover the side surface 9bc of the second bank layer 169B, and may be entirely in contact with the side surface 9bc of the second bank layer 169B. However, the first encapsulation layer 171 may not be in contact with the top surface 9ba of the second bank layer 169B.

The second encapsulation layer 173 of an embodiment may fill the cavity formed between the first encapsulation layer 171 and the fifth bank structure 160-5. The second encapsulation layer 173 may entirely cover the top surface 9ba of the second bank layer 169B included in the fifth bank structure 160-5, and may be entirely in contact with the top surface 9ba of the second bank layer 169B.

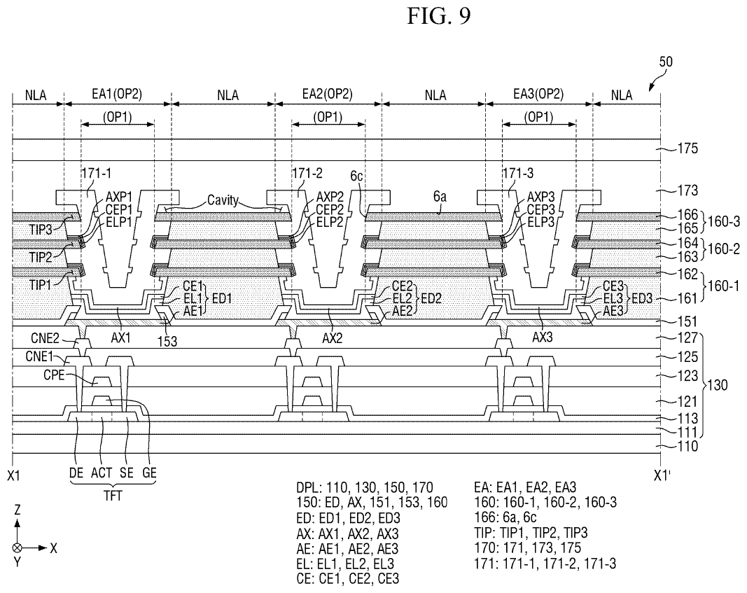

FIG. 9 is a schematic cross-sectional view of the display area DA taken along line X1-X1′ of FIG. 4 according to an embodiment.

Referring to FIG. 9, a display device 50 of an embodiment is different from the above-described display device 10 in that the bank structure 160 includes the first bank structure 160-1, the second bank structure 160-2, and the third bank structure 160-3. That is, the display area DA in FIG. 9 includes three pairs of bank layers making up the first bank structure 160-1, the second bank structure 160-2, and the third bank structure 160-3, where the third bank structure 160-3 provides the uppermost bank structure. Hereinafter, the common description of the display device 10 and the display device 50 will be omitted, and the differences will be described later.

In some embodiments, the top surface 6a of the second bank layer 166 included in the third bank structure 160-3 may be spaced apart from the first encapsulation layer 171 in the third direction (Z-axis direction). A cavity may be formed between the first encapsulation layer 171 and the top surface 6a of the second bank layer 166. Redundant descriptions of the cavity are omitted.

The first to third organic patterns ELP1, ELP2, and ELP3, the first to third electrode patterns CEP1, CEP2, and CEP3, and the first to third auxiliary electrode patterns AXP1, AXP2, and AXP3 may not be located on the third tip TIP3 of an embodiment.

The first encapsulation layer 171 of an embodiment may entirely cover the side surface 6c of the second bank layer 166, and may be entirely in contact with the side surface 6c of the second bank layer 166. However, the first encapsulation layer 171 may not be in contact with the top surface 6a of the second bank layer 166.

The second encapsulation layer 173 of an embodiment may fill the cavity formed between the first encapsulation layer 171 and the third bank structure 160-3. The second encapsulation layer 173 may entirely cover the top surface 6a of the second bank layer 166 included in the third bank structure 160-3, and may be entirely in contact with the top surface 6a of the second bank layer 166.

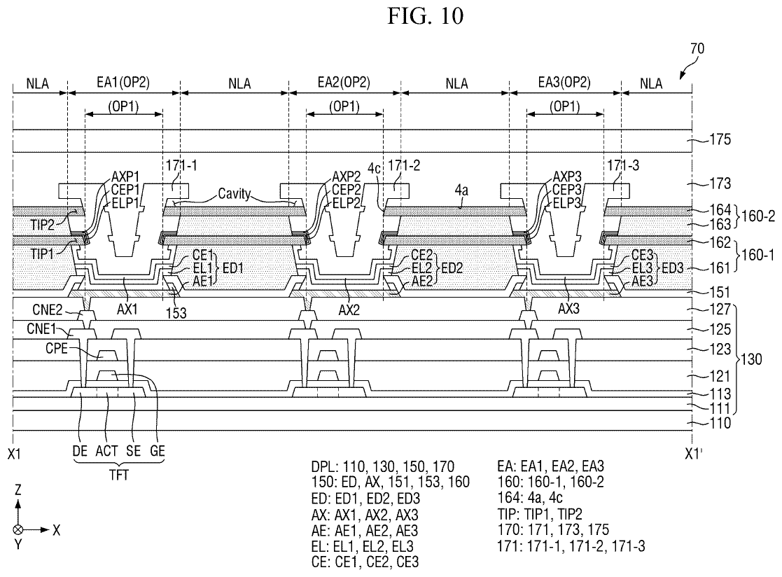

FIG. 10 is a schematic cross-sectional view of the display area taken along line X1-X1′ of FIG. 4 according to an embodiment.

Referring to FIG. 10, a display device 70 of an embodiment is different from the above-described display device 10 in that the bank structure 160 includes the first bank structure 160-1 and the second bank structure 160-2. That is, the display area DA in FIG. 10 includes two pairs of bank layers making up the first bank structure 160-1 and the second bank structure 160-2, where the second bank structure 160-2 provides the uppermost bank structure. Hereinafter, the common description of the display device 10 and the display device 70 will be omitted, and the differences will be described later.

In some embodiments, the top surface 4a of the second bank layer 164 included in the second bank structure 160-2 may be spaced apart from the first encapsulation layer 171 in the third direction (Z-axis direction). A cavity may be formed between the first encapsulation layer 171 and the top surface 4a of the second bank layer 164. Redundant descriptions of the cavity are omitted.

The first to third organic patterns ELP1, ELP2, and ELP3, the first to third electrode patterns CEP1, CEP2, and CEP3, and the first to third auxiliary electrode patterns AXP1, AXP2, and AXP3 may not be located on the second tip TIP2 of an embodiment.

The first encapsulation layer 171 of an embodiment may entirely cover the side surface 4c of the second bank layer 164, and may be entirely in contact with the side surface 4c of the second bank layer 164. However, the first encapsulation layer 171 may not be in contact with the top surface 4a of the second bank layer 164.

The second encapsulation layer 173 of an embodiment may fill the cavity formed between the first encapsulation layer 171 and the second bank structure 160-2. The second encapsulation layer 173 may entirely cover the top surface 4a of the second bank layer 164 included in the second bank structure 160-2, and may be entirely in contact with the top surface 4a of the second bank layer 164.

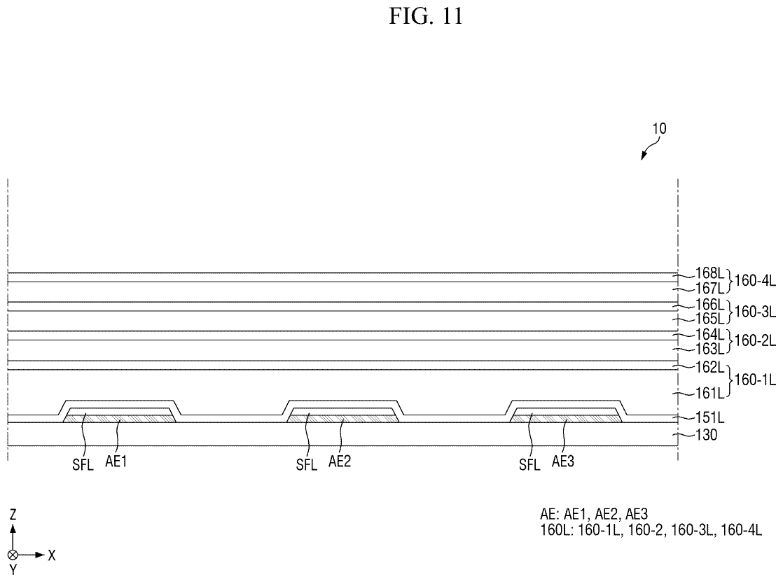

FIGS. 11 to 20 are cross-sectional views illustrating an embodiment of a schematic method of fabricating (or providing) the display element layer 150 and the thin film encapsulation layer 170 included in the display device 10 of FIG. 5. Hereinafter, the formation order of each layer in the fabrication process of the display element layer 150 and the thin film encapsulation layer 170 shown in FIG. 5 will be described.

Referring to FIG. 11, a plurality of anode electrodes AE of an anode electrode layer, a sacrificial layer SFL including a plurality of sacrificial patterns, a pixel defining material layer 151L, and a bank structure material layer 160L including pairs of bank layers may be included on the thin film transistor layer 130. Although not illustrated in the drawing, the thin film transistor layer 130 may be disposed on the substrate 110, and the structure of the thin film transistor layer 130 is the same as that described above with reference to FIG. 5. A detailed description thereof is omitted.

Solid portions of the anode electrode AE may include the first to third anode electrodes AE1, AE2, and AE3 disposed to be spaced apart from each other on the thin film transistor layer 130. Solid portions of the sacrificial layer SFL may be located on each of the first to third anode electrodes AE1, AE2, and AE3. The sacrificial layer SFL may assist in preventing the top surfaces of the first to third anode electrodes AE1, AE2, and AE3 from being in contact with the pixel defining material layer 151L.

The sacrificial layer SFL may include an oxide semiconductor. For example, the sacrificial layer SFL may include at least one of indium-gallium-zinc oxide (IGZO), zinc-tin oxide (ZTO), and indium-tin oxide (ITO).

The pixel defining material layer 151L may be disposed to entirely cover the sacrificial layer SFL, the anode electrode Ae and the thin film transistor layer 130, and the bank structure material layer 160L may be located to entirely cover the pixel defining material layer 151L. The bank structure material layer 160L may include first to fourth bank structure material layers 160-1L, 160-2L, 160-3L, and 160-4L sequentially stacked in the third direction (Z-axis direction). Each of the first to fourth bank structure material layers 160-1L, 160-2L, 160-3L, and 160-4L includes a pair of bank material layers, such as an upper bank layer and a lower bank layer. The first to fourth bank structure material layers 160-1L, 160-2L, 160-3L, and 160-4L may be respective preliminary bank structure layers. For example, the first bank structure material layer 160-1L may include a first bank material layer 161L and a second bank material layer 162L stacked in that order as a first pair of preliminary bank layers, the second bank structure material layer 160-2L may include a first bank material layer 163L and a second bank material layer 164L stacked in that order as a second pair of preliminary bank layers, the third bank structure material layer 160-3L may include a first bank material layer 165L and a second bank material layer 166L stacked in that order as a third pair of preliminary bank layers, and the fourth bank structure material layer 160-4L may include a first bank material layer 167L and a second bank material layer 168L stacked in that order as a fourth pair of preliminary bank layers.

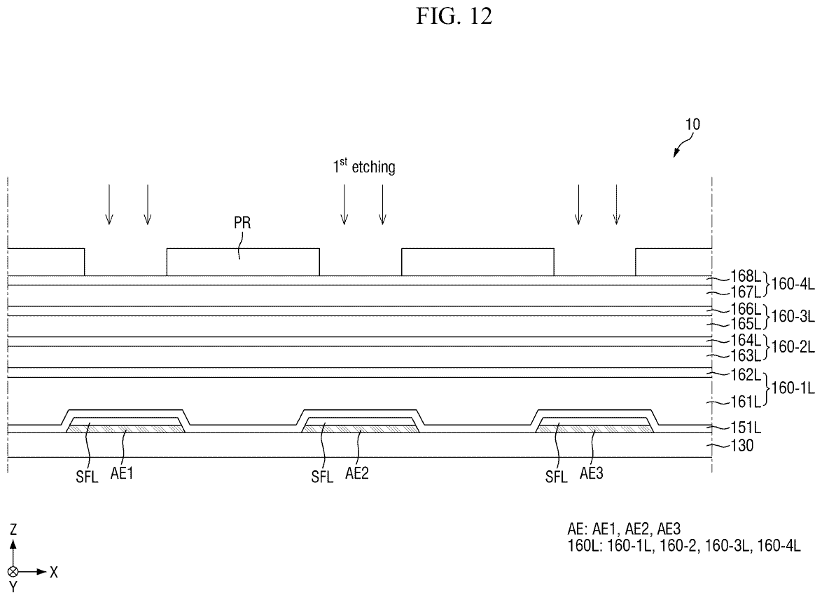

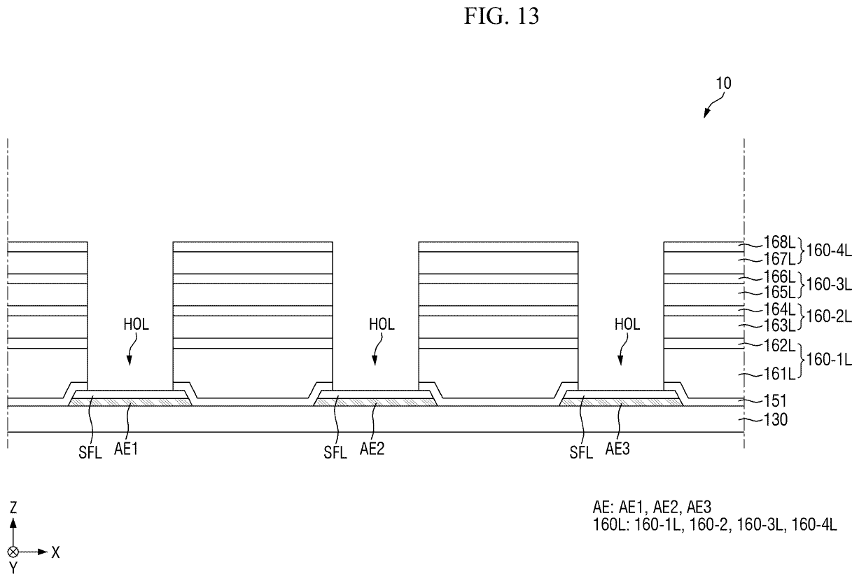

Next, referring to FIGS. 12 and 13, a photoresist PR as a first photoresist is formed on the uppermost preliminary bank layer (e.g., the fourth bank structure material layer 160-4L) while exposing a portion of the uppermost preliminary bank layer which overlaps or corresponds to the anode electrodes AE. Next, a first etching process (1^{st} etching) for partially etching the first to fourth bank structure material layers 160-1L, 160-2L, 160-3L, and 160-4L and the underlying the pixel defining material layer 151L while using the photoresist PR as a mask is performed. For example, the first etching process (1^{st} etching) may be performed as dry etching. Since the first etching process (1^{st} etching) is performed as a dry etching process, the bank structure material layer 160L and the pixel defining material layer 151L which overlaps the anode electrode AE may be partially isotropically etched. The first to fourth bank structure material layers 160-1L, 160-2L, 160-3L, and 160-4L and the underlying the pixel defining material layer 151L may together define a first stacked structure.

Due to this process, a hole HOL (e.g., a preliminary pixel opening, a preliminary bank opening, a preliminary emission opening, etc.) may be formed at a portion overlapping the first to third anode electrodes AE1, AE2, and AE3, and the sacrificial layer SFL disposed on the anode electrode AE may be exposed. Due to this process, the pixel defining material layer 151L may be formed in the form of the pixel defining layer 151 shown in FIG. 5. Here, the sacrificial layer SFL is exposed to outside the first stacked structure at each of the preliminary emission openings (e.g., the holes HOL).

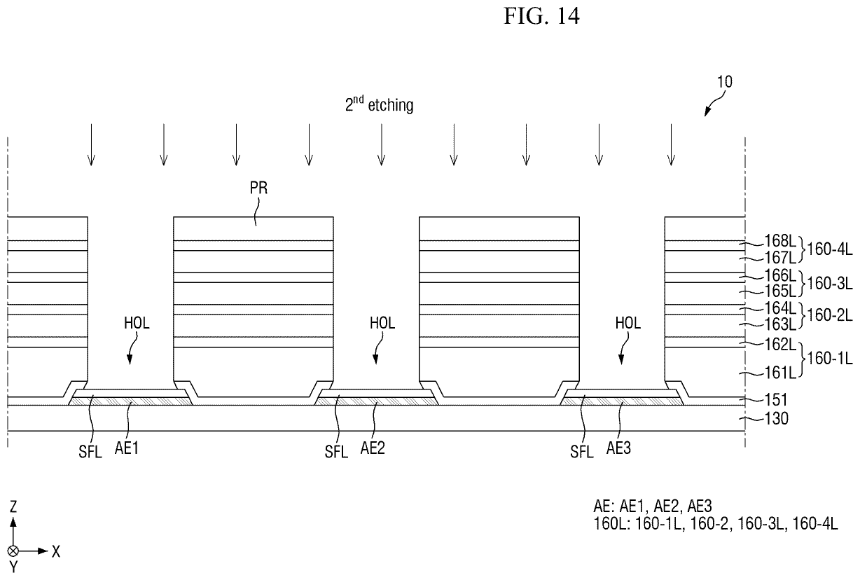

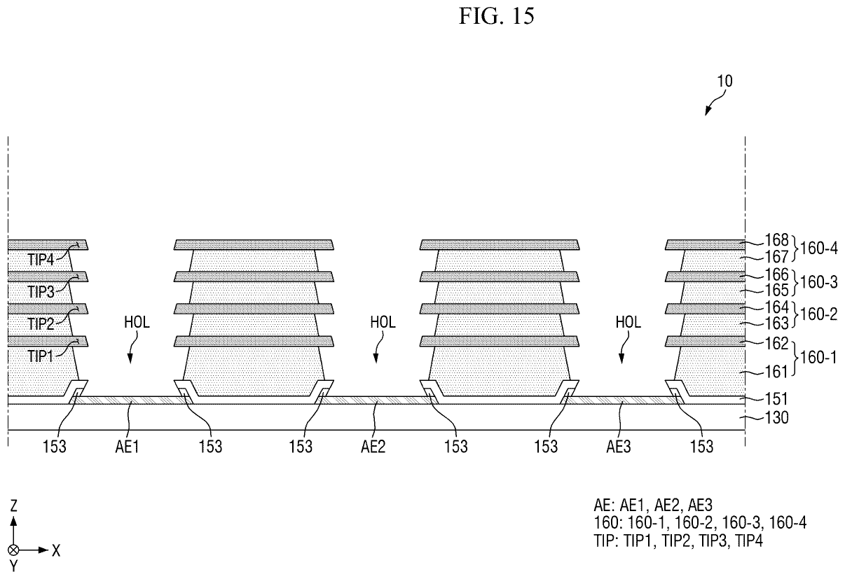

Next, referring to FIGS. 14 and 15, the photoresist PR as a second photoresist is formed on the fourth bank structure material layer 160-4L, and a second etching process (2^{nd} etching) for etching exposed layers which are at the inside of the hole HOL and overlapping the first to third anode electrodes AE1, AE2, and AE3 is performed. For example, the second etching process (2^{nd} etching) may be performed as a wet etching process. The second etching process (2^{nd} etching) may be anisotropically performed depending on the characteristics of each material layer.

In this process, a sidewall of the pixel defining layer 151 which defines the pixel opening (e.g., at the emission opening) is etched to form an inclined inner side surface (see FIG. 13 to FIG. 14). Also in this process (see FIG. 13 to FIG. 15), the first bank material layer 161L and the second bank material layer 162L included in the first bank structure material layer 160-1L may be formed in the form of the first bank layer 161 and the second bank layer 162 included in the first bank structure 160-1 shown in FIG. 5, and the first bank material layer 163L and the second bank material layer 164L included in the second bank structure material layer 160-2L may be formed in the form of the first bank layer 163 and the second bank layer 164 included in the second bank structure 160-2 shown in FIG. 5. Further, the first bank material layer 165L and the second bank material layer 166L included in the third bank structure material layer 160-3L may be formed in the form of the first bank layer 165 and the second bank layer 166 included in the third bank structure 160-3 shown in FIG. 5, and the first bank material layer 167L and the second bank material layer 168L included in the fourth bank structure material layer 160-4L may be formed in the form of the first bank layer 167 and the second bank layer 168 included in the fourth bank structure 160-4 shown in FIG. 5.

In this process, the material for forming the second bank layer 162 included in the first bank structure 160-1 may have an etching rate lower than that of the first bank layer 161. In other words, in the same etching process, the material for forming the first bank layer 161 of an embodiment may have an etching rate higher than that of the second bank layer 162. Accordingly, the second bank layer 162 of an embodiment may have the first tip TIP1 which protrudes toward the hole HOL beyond the side surface of the first bank layer 161. In addition, the material for forming the second bank layer 164 included in the second bank structure 160-2 may have an etching rate lower than that of the first bank layer 163, so that the second bank layer 164 of an embodiment may have the second tip TIP2 which protrudes toward the hole HOL beyond the side surface of the first bank layer 163. Further, the material for forming the second bank layer 166 included in the third bank structure 160-3 may have an etching rate lower than that of the first bank layer 165, so that the second bank layer 166 of an embodiment may have the third tip TIP3 which protrudes toward the hole HOL beyond the side surface of the first bank layer 165. In addition, the material for forming the second bank layer 168 included in the fourth bank structure 160-4 may have an etching rate lower than that of the first bank layer 167, so that the second bank layer 168 of an embodiment may have the fourth tip TIP4 which protrudes toward the hole HOL beyond the side surface of the first bank layer 167.

At the same time, a part of the sacrificial layer SFL disposed on the first to third anode electrodes AE1, AE2, and AE3 and exposed at the preliminary emission opening may be removed in this process. However, the sacrificial layer SFL may not be completely removed and a portion thereof may remain as the residual pattern 153 in the space between the pixel defining layer 151 and the first to third anode electrodes AE1, AE2, and AE3. The residual pattern 153 may overlap the tip TIP of the bank structure 160 in the third direction (Z-axis direction). Other redundant descriptions are omitted.

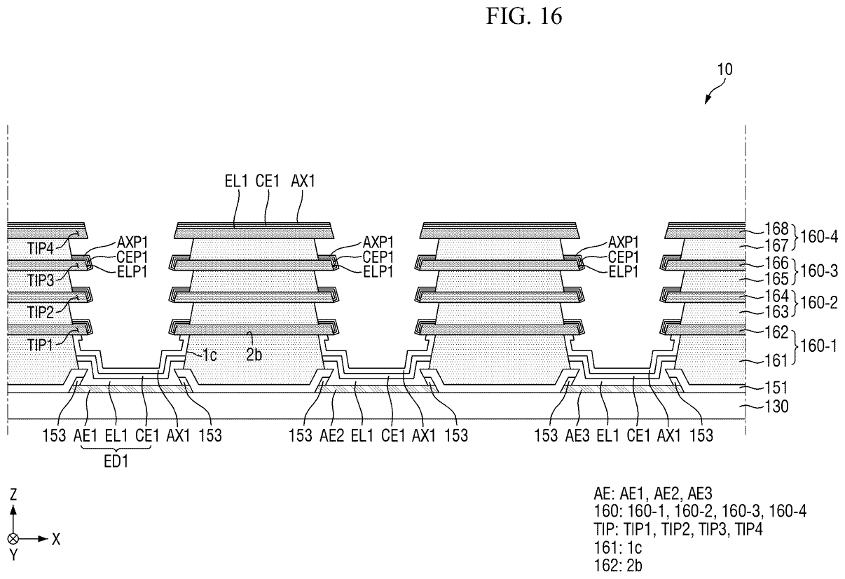

Next, referring to FIG. 16, the first light emitting layer EL1 and the first cathode electrode CE1 are deposited on the first anode electrode AE1, thereby forming the first light emitting element ED1. The aforementioned layers forming the first light emitting element ED1 may be provided at each of the holes HOL.

The first light emitting layer EL1 and the first cathode electrode CE of an embodiment may be formed by a thermal deposition process. In the display device 10 of an embodiment, the bank structure 160 includes the tip TIP, so that the deposition process for forming the first light emitting layer EL1 and the deposition process for forming the first cathode electrode CE1 may be performed without a separate fine metal mask.

In this process, the deposition process for forming the first light emitting layer EL1 may be performed while a first light emitting material is provided being tilted at an angle of about 45° to about 50° from (or relative to) the top surface of the first anode electrode AE1. Accordingly, the first light emitting layer EL1 may be formed on the pixel defining layer 151 and deposited on the first anode electrode AE1, and may also be formed on the side surface 1c of the first bank layer 161 covered by the first tip TIP1. The first light emitting layer EL1 described above may be provided at each of the holes HOL.

The deposition process for forming the first cathode electrode CE1 in an embodiment may be performed while a cathode electrode material is provided by being tilted at an angle of about 30° or less from the top surface of the first anode electrode AE1. In other words, the deposition process for forming the first cathode electrode CE1 may be performed by being tilted at an angle relatively closer to a horizontal direction than the deposition process for forming the first light emitting layer EL1. Accordingly, the first cathode electrode CE1 may be deposited on the first anode electrode AE1 and formed on the pixel defining layer 151, and may also be formed on the side surface 1c of the first bank layer 161 covered by the first tip TIP1. The first cathode electrode CE1 may completely cover the first light emitting layer EL1. The material forming the first light emitting layer EL1 and the material forming the first cathode electrode CE1 in an embodiment may be formed on the first anode electrode AE1, and may also be formed on the second anode electrode AE2, the third anode electrode AE3, the first tip TIP1, the second tip TIP2, the third tip TIP3, and the second bank layer 168 included in the fourth bank structure 160-4. Due to this process, the first organic pattern ELP1 and the first electrode pattern CEP1 may be formed on the first tip TIP1, the second tip TIP2, and the third tip TIP3 which are adjacent to the holes HOL. As described above, the first organic pattern ELP1 and the first electrode pattern CEP1 may be traces formed since the material forming the first light emitting layer EL1 and the material forming the first cathode electrode CE1 are disconnected due to the tip TIP of the bank structure 160. That is, the first organic pattern ELP1 and the first light emitting layer EL1 may correspond to a same color emission area (e.g., the first emission area EA1).

Next, the first auxiliary electrode AX1 is formed on the first light emitting element ED1. The first auxiliary electrode AX1 of an embodiment may be formed by a sputtering device. Accordingly, the process for forming the first auxiliary electrode AX1 in an embodiment may have higher step coverage characteristics compared to the process for forming the first light emitting layer EL1 and the first cathode electrode CE1. Therefore, the first auxiliary electrode AX1 of an embodiment may entirely cover the first light emitting layer EL1 and the first cathode electrode CE1, and may be in contact with the side surface 1c of the first bank layer 161 and the bottom surface 2b of the second bank layer 162. Redundant descriptions are omitted.

In addition, the material forming the first auxiliary electrode AX1 of an embodiment may be formed on the first light emitting element ED1, and may also be formed on the second anode electrode AE2, the third anode electrode AE3, the first tip TIP1, the second tip TIP2, the third tip TIP3, and the second bank layer 168 included in the fourth bank structure 160-4. Due to this process, the first auxiliary electrode pattern AXP1 may be formed on the first tip TIP1, the second tip TIP2, and the third tip TIP3. As described above, the first auxiliary electrode pattern AXP1 may be a trace formed since the material forming the first auxiliary electrode AX1 is disconnected without being connected with the first auxiliary electrode AX1 due to the tip TIP of the bank structure 160. The first auxiliary electrode pattern AXP1 may entirely cover the first organic pattern ELP1 and the first electrode pattern CEP1. Redundant descriptions are omitted.

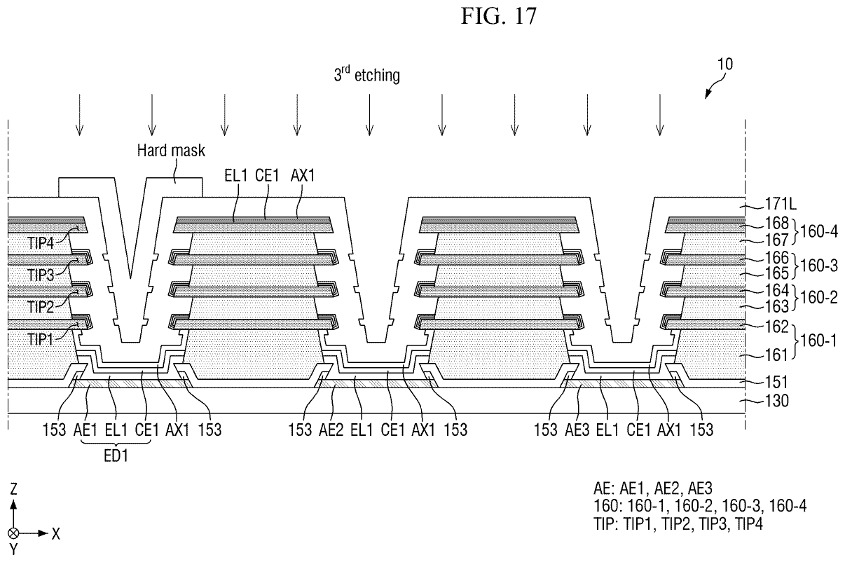

Next, referring to FIG. 17, a first encapsulation material layer 171L is entirely formed on the first auxiliary electrode AX1 and the first auxiliary electrode pattern AXP1. The first encapsulation material layer 171L together with the layers thereunder may define a second stacked structure. The first encapsulation material layer 171L may be formed by a chemical vapor deposition (CVD) process, and may be formed with a uniform thickness along the profile formed by the lower structure. That is, the first encapsulation material layer 171L may include a stepped portion at a portion overlapping the anode electrode AE and the bank structure 160.

Next, a hard mask is formed at a portion overlapping the first light emitting element ED1 of the first emission area EA1 and extending from the first emission area EA1 to an area adjacent thereto, as the vicinity of the first light emitting element ED1, and a third etching process (3^{rd} etching) for etching a portion where the hard mask is not formed is performed. For example, the third etching process (3^{rd} etching) may be performed by alternately performing a dry etching process and a wet etching process. In this process, the first light emitting layer EL1, the first cathode electrode CE1, the first auxiliary electrode AX1, the first organic pattern ELP1, the first electrode pattern CEP1, the first auxiliary electrode pattern AXP1 and the first encapsulation material layer 171L arranged at areas where the hard mask is not formed may be entirely removed. The hard mask used in this process may be indium gallium zinc oxide (IGZO). That is, the first light emitting layer EL1, the first cathode electrode CE1, the first auxiliary electrode AX1, the first organic pattern ELP1, the first electrode pattern CEP1, the first auxiliary electrode pattern AXP1 and the first encapsulation material layer 171L remain within the emission opening at the first emission area EA1.

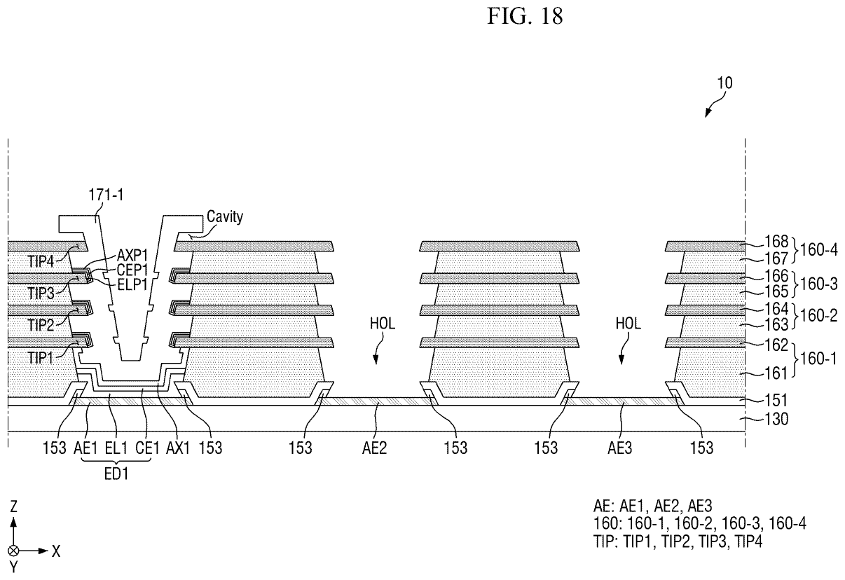

As shown in FIG. 18, due to this process, the first encapsulation material layer 171L may be formed in the form of the first inorganic layer 171-1 shown in FIG. 5, and a cavity may be formed between the first inorganic layer 171-1 and the second bank layer 168 included in the fourth bank structure 160-4 in the third direction (Z-axis direction). The cavity may be formed by etching the material forming the first light emitting layer EL1, the material forming the first cathode electrode CE1, and the material forming the first auxiliary electrode AX1, which were disposed on the second bank layer 168 adjacent to the first emission area EA1, by the third etching process (3^{rd} etching). In this process, one surface of the second bank layer 168 facing the cavity may be exposed to outside the the first inorganic layer 171-1.

At the same time, due to this process, the second anode electrode AE2 and the third anode electrode AE3 at different color emission areas from the first emission area EA1 may be exposed again, the residual pattern 153 overlapping the second anode electrode AE2 and the third anode electrode AE3 may remain, and the hole HOL may be re-opened at a portion overlapping the second anode electrode AE2 and the third anode electrode AE3.

Next, the above-described processes are repeated to form the second light emitting element ED2 and the third light emitting element ED3. That is, the processes may be repeated for different color emission areas as defined by respective light emitting material layers.

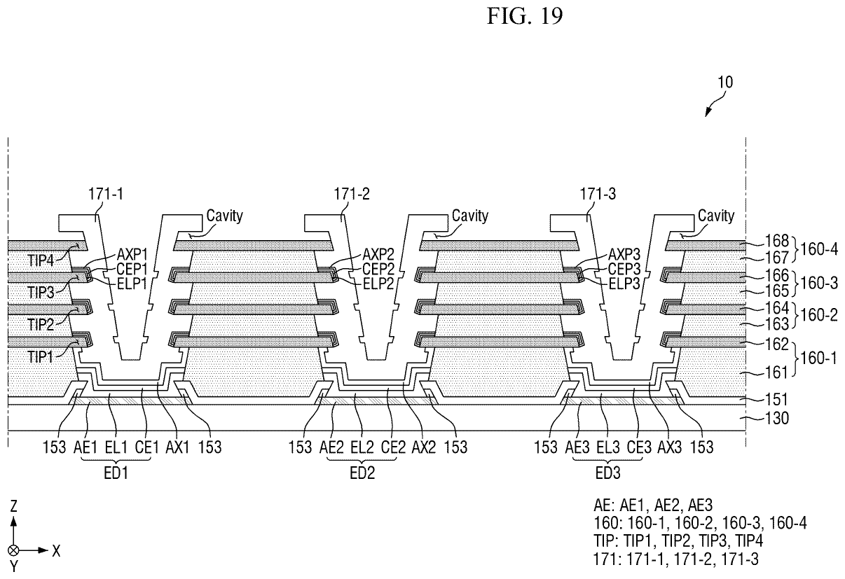

Referring to FIG. 19, due to this process, the second organic pattern ELP2, the second electrode pattern CEP2, and the second auxiliary electrode pattern AXP2 may be formed on the first tip TIP1, the second tip TIP2, and the third tip TIP3 each located to overlap the second light emitting element ED2 at the second emission area EA2. In addition, the third organic pattern ELP3, the third electrode pattern CEP3, and the third auxiliary electrode pattern AXP3 may be formed on the first tip TIP1, the second tip TIP2, and the third tip TIP3 each located to overlap the third light emitting element ED3 at the third emission area EA3.

Further, due to this process, the second inorganic layer 171-2 and the third inorganic layer 171-3 shown in FIG. 5 may be formed, thereby forming the first encapsulation layer 171 together with the first inorganic layer 171-1 previously formed. A cavity may be formed between the second inorganic layer 171-2 and the second bank layer 168 in the third direction (Z-axis direction), and a cavity may also be formed between the third inorganic layer 171-3 and the second bank layer 168 in the direction (Z-axis direction). Redundant descriptions are omitted.

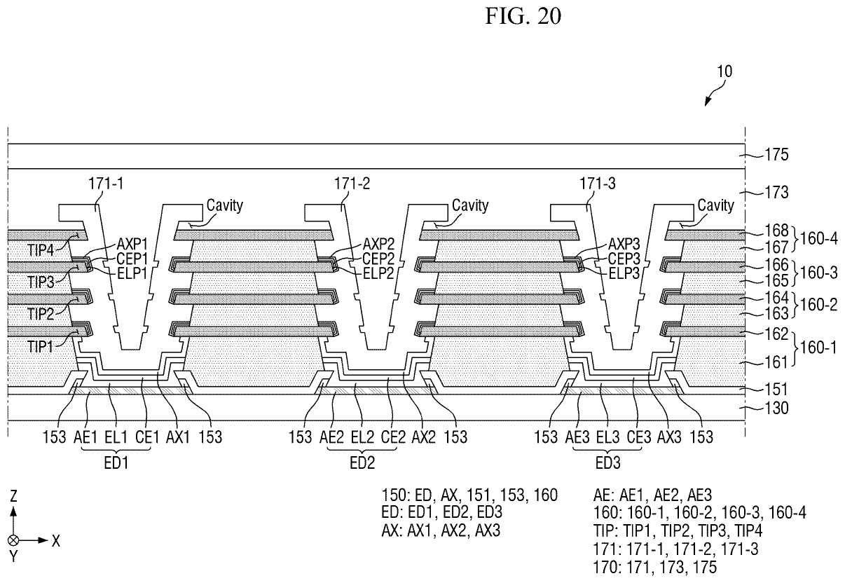

Next, referring to FIG. 20, the second encapsulation layer 173 is formed to flatten the stepped portion included in the first encapsulation layer 171 and, then, the third encapsulation layer 175 is formed on the second encapsulation layer 173, thereby forming the thin film encapsulation layer 170 shown in FIG. 5.

In this process, the second encapsulation layer 173 may fill the inside of the cavities located between the fourth bank structure 160-4 and the first encapsulation layer 171. In other words, the fourth bank structure 160-4 and the first encapsulation layer 171 may be spaced apart in the third direction (Z-axis direction) with the second encapsulation layer 173 interposed therebetween. In addition, the first inorganic layer 171-1, the second inorganic layer 171-2, and the third inorganic layer 171-3 may be spaced apart in the first direction (X-axis direction) with the second encapsulation layer 173 interposed therebetween. As a result, the display element layer 150 and the thin film encapsulation layer 170 included in the display device 10 of an embodiment may be formed.

In an embodiment, a display device includes a display area DA including an emission area EA and a non-emission area NLA. The non-emission area NLA includes a pixel defining layer 151, and first and second bank structures each including a pair of bank layer having a first bank layer including a side surface facing the emission area EA and a second bank layer including a tip TIP which protrudes further than the side surface of the first bank layer. The emission area EA includes a light emitting layer EL in contact with the side surface of the first bank layer, a cathode electrode CE on the light emitting layer EL and in contact with the side surface of the first bank layer, and an auxiliary electrode AX on the cathode electrode CE and in contact with the side surface of the first bank layer and with the of the second bank layer, and a first encapsulation layer 171 on the second bank structure and on the auxiliary electrode AX.

The display device may further include an organic layer (EL and ELP) including the light emitting layer and an organic pattern which is on the first tip and disconnected from the light emitting layer, a cathode electrode layer (CE and CEP) including the cathode electrode and an electrode pattern which is on the organic pattern and disconnected from the cathode electrode, an an auxiliary electrode layer (AX and AXP) including the auxiliary electrode and an auxiliary electrode pattern which is on the electrode pattern and disconnected from the auxiliary electrode. The organic pattern, the electrode pattern and the auxiliary electrode pattern may overlap each other along a thickness direction of the substrate 110.

The display device may further include a residual pattern 153 which is in the light emission area and overlaps the first tip and the second tip. Within the emission area EA the anode electrode and the pixel defining layer are spaced apart from each other with a gap therebetween, and the residual pattern is in the gap between the anode electrode and the pixel defining layer.

The first encapsulation layer may extend from the emission area to overlap a portion of the upper surface of the uppermost bank layer which is adjacent to the emission area.

The display device may further include a second encapsulation layer on the first encapsulation layer. The upper surface of the uppermost bank layer and the first encapsulation layer are spaced apart from each other with a gap therebetween, and the second encapsulation layer extends into the gap between the upper surface of the uppermost bank layer and the first encapsulation layer.

In an embodiment, a method providing a display device includes providing a substrate including a display area including a light emission area and a non-emission area, and a non-display area which is adjacent to the display area. The method further includes in the display area, providing an anode electrode of a light emitting element and a sacrificial layer which is on the anode electrode, in the emission area, providing a pixel defining layer on the sacrificial layer and on the non-emission area of the substrate, providing a bank structure including a first bank layer, a second bank layer, a third bank layer, a fourth bank layer, a fifth bank layer, a sixth bank layer, a seventh bank layer, and an eighth bank layer which are sequentially stacked on the pixel defining layer (refer to FIG. 11, for example), providing a photoresist pattern on the eighth bank layer to expose an area of the bank structure which overlaps the anode electrode, at the area of the bank structure, removing the bank structure and the pixel defining layer through a first etching process using the photoresist pattern (refer to FIG. 12, for example), the first etching process including forming a hole in the bank structure and in the pixel defining layer which corresponds to the emission area, the hole exposing the sacrificial layer to outside the bank structure and the pixel defining layer, and forming a side surface for each of the first bank layer, the second bank layer, the third bank layer, the fourth bank layer, the fifth bank layer, the sixth bank layer, the seventh bank layer and the eighth bank layer which is exposed to the hole (refer to FIG. 13, for example), within the hole, performing a second etching process to remove a portion of the sacrificial layer which is exposed by the hole together with providing a first tip of the second bank layer which protrudes further than the side surface of the first bank layer, a second tip of the fourth bank layer which protrudes further than the side surface of the third bank layer, a third tip of the sixth bank layer which protrudes further than the side surface of the fifth bank layer, and a fourth tip of the eighth bank layer which protrudes further than the side surface of the seventh bank layer (refer to FIGS. 14 and 15, for example), providing an organic layer, a cathode electrode layer, an auxiliary electrode layer and a first encapsulation layer in order on the anode electrode and on the eighth bank layer, to form the organic layer including a light emitting layer on the anode electrode and an organic pattern which is on the first tip and disconnected from the light emitting layer, the cathode electrode layer including the cathode electrode on the light emitting layer and an electrode pattern which is on the organic pattern and disconnected from the cathode electrode, the auxiliary electrode layer including the auxiliary electrode on the cathode electrode and an auxiliary electrode pattern which is on the electrode pattern and disconnected from the auxiliary electrode, and the auxiliary electrode in contact with the side surface of the first bank layer and the first tip of the second bank layer (refer to FIG. 16, for example), providing a mask pattern (e.g., hard mask) on the first encapsulation layer, the mask pattern overlapping the hole and an area of the bank structure which is adjacent to the hole and removing portions of each of the organic layer, the cathode electrode layer, the auxiliary electrode layer and the first encapsulation layer except for an area overlapping the mask pattern through a third etching process (refer to FIG. 17, for example), the third etching process including forming a light emitting element including the anode electrode, the light emitting layer and the cathode electrode, maintaining the organic pattern, the electrode pattern and the auxiliary electrode pattern on each of the first tip, the second tip, and the third tip, and forming a cavity between the first encapsulation layer and a top surface of the eighth bank layer, the cavity exposing a top surface of the eighth bank layer to outside the first encapsulation layer (refer to FIG. 18, for example).

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a display area including an emission area and a non-emission area, and a non-display area adjacent to the display area;
the non-emission area comprising:
a pixel defining layer;
a first bank structure on the pixel defining layer, the first bank structure comprising a first bank layer including a side surface facing the emission area and a second bank layer which is on the first bank layer and includes a first tip which protrudes further than the side surface of the first bank layer; and
a second bank structure on the first bank structure, the second bank structure comprising a third bank layer including a side surface facing the emission area and a fourth bank layer which is on the third bank layer and includes a second tip which protrudes further than the side surface of the third bank layer;
the emission area comprising:
a light emitting layer of a light emitting element which is in contact with the side surface of the first bank layer;
a cathode electrode of the light emitting element which is on the light emitting layer and in contact with the side surface of the first bank layer; and
an auxiliary electrode on the cathode electrode and in contact with the side surface of the first bank layer and with the first tip of the second bank layer; and
a first encapsulation layer on the second bank structure and on the auxiliary electrode.

2. The display device of claim 1, further comprising:
an organic layer comprising the light emitting layer and an organic pattern which is on the first tip and disconnected from the light emitting layer;
a cathode electrode layer comprising the cathode electrode and an electrode pattern which is on the organic pattern and disconnected from the cathode electrode; and
an auxiliary electrode layer comprising the auxiliary electrode and an auxiliary electrode pattern which is on the electrode pattern and disconnected from the auxiliary electrode.

3. The display device of claim 2, wherein along the first tip:
the electrode pattern entirely covers the organic pattern, and
the auxiliary electrode pattern entirely covers the electrode pattern.

4. The display device of claim 2, wherein within the first bank structure:
the second bank layer includes a side surface facing the emission area, and
the side surface of the second bank layer comprises a first portion in contact with the organic pattern, a second portion in contact with the electrode pattern, and a third portion in contact with the auxiliary electrode pattern.

5. The display device of claim 4, wherein along the side surface of the second bank layer, the second portion is between the first portion and the third portion.

6. The display device of claim 2, wherein the organic pattern, the electrode pattern and the auxiliary electrode pattern overlap each other along a thickness direction of the substrate.

7. The display device of claim 2, wherein within the first bank structure:
the second bank layer includes a first surface facing the first bank layer,
the first surface of the second bank layer comprises a first portion in contact with the first bank layer, a second portion in contact with the auxiliary electrode, and a third portion in contact with the first encapsulation layer, and
the second portion is between the first portion and the third portion.

8. The display device of claim 7, wherein the first surface of the second bank layer is entirely covered by the first bank layer, the auxiliary electrode and the first encapsulation layer.

9. The display device of claim 2, wherein within the second bank structure:
the fourth bank layer includes a side surface facing the emission area and an upper surface which is extended from the side surface of the fourth bank layer, and
the side surface of the fourth bank layer is entirely in contact with the first encapsulation layer.

10. The display device of claim 9, further comprising a second encapsulation layer on the first encapsulation layer,
wherein
the upper surface of the fourth bank layer and the first encapsulation layer are spaced apart from each other with a gap therebetween, and
the second encapsulation layer extends into the gap between the upper surface of the fourth bank layer and the first encapsulation layer.

11. The display device of claim 10, wherein the upper surface of the fourth bank layer is entirely in contact with the second encapsulation layer.

12. The display device of claim 11, wherein the first encapsulation layer extends from the emission area to overlap a portion of the upper surface of the fourth bank layer which is adjacent to the emission area.

13. The display device of claim 2, further comprising a residual pattern which is in the light emission area and overlaps the first tip and the second tip,
wherein within the emission area:
an anode electrode of the light emitting element and the pixel defining layer are spaced apart from each other with a gap therebetween, and
the residual pattern is in the gap between the anode electrode and the pixel defining layer.

14. The display device of claim 13, wherein the residual pattern overlaps the organic pattern, the electrode pattern and the auxiliary electrode pattern.

15. The display device of claim 2, further comprising a third bank structure between the first bank structure and the second bank structure along a thickness direction of the substrate,
wherein
the third bank structure comprises a fifth bank layer including a side surface which faces the emission area and a sixth bank layer which is on the fifth bank layer and includes a third tip which protrudes further than the side surface of the fifth bank layer, and
the organic pattern, the electrode pattern and the auxiliary electrode pattern are further on the third tip.

16. The display device of claim 15, wherein the organic pattern, the electrode pattern and the auxiliary electrode pattern which are on the first tip, and the organic pattern, the electrode pattern and the auxiliary electrode pattern which are on the third tip overlap each other along the thickness direction of the substrate.

17. The display device of claim 16, wherein
the first encapsulation layer entirely covers the first tip, the second tip and the third tip, and
the side surface of the third bank layer and the side surface of the fifth bank layer are in contact with the first encapsulation layer.

18. The display device of claim 15, further comprising a fourth bank structure between the second bank structure and the third bank structure along the thickness direction of the substrate,
wherein
the fourth bank structure comprises a seventh bank layer including a side surface facing the emission area and an eighth bank layer which is on the seventh bank layer and includes a fourth tip which protrudes further than the side surface of the seventh bank layer, and
the organic pattern, the electrode pattern and the auxiliary electrode pattern are further on the fourth tip.

19. The display device of claim 1, wherein a height of the first bank layer is greater than a height of the second bank layer along a thickness direction of the substrate.

20. A method of providing a display device, comprising:
providing a substrate comprising a display area including a light emission area and a non-emission area, and a non-display area which is adjacent to the display area; and
in the display area:
providing an anode electrode of a light emitting element and a sacrificial layer which is on the anode electrode, in the emission area;
providing a pixel defining layer on the sacrificial layer and on the non-emission area of the substrate;
providing a bank structure comprising a first bank layer, a second bank layer, a third bank layer, a fourth bank layer, a fifth bank layer, a sixth bank layer, a seventh bank layer, and an eighth bank layer which are sequentially stacked on the pixel defining layer;
providing a photoresist pattern on the eighth bank layer to expose an area of the bank structure which overlaps the anode electrode;
at the area of the bank structure, removing the bank structure and the pixel defining layer through a first etching process using the photoresist pattern, the first etching process including:
forming a hole in the bank structure and in the pixel defining layer which corresponds to the emission area, the hole exposing the sacrificial layer to outside the bank structure and the pixel defining layer, and
forming a side surface for each of the first bank layer, the second bank layer, the third bank layer, the fourth bank layer, the fifth bank layer, the sixth bank layer, the seventh bank layer and the eighth bank layer which is exposed to the hole;
within the hole, performing a second etching process to remove a portion of the sacrificial layer which is exposed by the hole together with providing a first tip of the second bank layer which protrudes further than the side surface of the first bank layer, a second tip of the fourth bank layer which protrudes further than the side surface of the third bank layer, a third tip of the sixth bank layer which protrudes further than the side surface of the fifth bank layer, and a fourth tip of the eighth bank layer which protrudes further than the side surface of the seventh bank layer;
providing an organic layer, a cathode electrode layer, an auxiliary electrode layer and a first encapsulation layer in order on the anode electrode and on the eighth bank layer, to form:
the organic layer comprising a light emitting layer on the anode electrode and an organic pattern which is on the first tip and disconnected from the light emitting layer,
the cathode electrode layer comprising the cathode electrode on the light emitting layer and an electrode pattern which is on the organic pattern and disconnected from the cathode electrode,
the auxiliary electrode layer comprising the auxiliary electrode on the cathode electrode and an auxiliary electrode pattern which is on the electrode pattern and disconnected from the auxiliary electrode, and
the auxiliary electrode in contact with the side surface of the first bank layer and the first tip of the second bank layer;
providing a mask pattern on the first encapsulation layer, the mask pattern overlapping the hole and an area of the bank structure which is adjacent to the hole; and
removing portions of each of the organic layer, the cathode electrode layer, the auxiliary electrode layer and the first encapsulation layer except for an area overlapping the mask pattern through a third etching process, the third etching process including:
forming a light emitting element including the anode electrode, the light emitting layer and the cathode electrode,
maintaining the organic pattern, the electrode pattern and the auxiliary electrode pattern on each of the first tip, the second tip, and the third tip, and
forming a cavity between the first encapsulation layer and a top surface of the eighth bank layer, the cavity exposing a top surface of the eighth bank layer to outside the first encapsulation layer.
